(19) United States
(12) Patent Application Publication
(10) Pub. No.: US 2025/0132297 A1
(43) Pub. Date: Apr. 24, 2025

(54) Thermal Conducting Structure for Vertically Integrated On-Chip Inductor Based IVR Chiplets with SoC

(71) Applicant: PowerLattice Technologies Inc., Camas, WA (US)

(72) Inventors: Gang Ren, Camas, WA (US); Peng Zou, Camas, WA (US); Sujith S. Dermal, Chandler, AZ (US)

(21) Appl. No.: 18/981,346

(22) Filed: Dec. 13, 2024

Related U.S. Application Data
(63) Continuation-in-part of application No. 18/919,345, filed on Oct. 17, 2024.
(60) Provisional application No. 63/592,109, filed on Oct. 20, 2023.
(60) Provisional application No. 63/611,066, filed on Dec. 15, 2023.

(51) Int. Cl. H01L 25/16; H01L 23/367

(52) U.S. Cl. CPC H01L 25/16; H01L 23/367

(57) ABSTRACT

This application is directed to providing a thermal path for a circuit package. The circuit package includes a plurality of chiplets. The circuit package further includes a substrate coupled to the plurality of chiplets. The circuit package further includes a processor coupled to the plurality of chiplets through the substrate. The circuit package further includes a printed circuit board coupled to the plurality of chiplets and including a thermal path between a first side and a second side of the printed circuit board. The thermal path is configured to dissipate heat from the plurality of chiplets to ambient.

### RELATED APPLICATION

This application is a continuation-in-part of U.S. patent application Ser. No. 18,919,345, entitled “Apparatus of Configurable PMIC With Array of Micro Integrated Voltage Regulation Cells And Shared Programmable References” filed Oct. 17, 2024, which claims the benefit of U.S. Provisional Patent Application No. 63/592, 109, titled “Apparatus of Configurable PMIC with Array of Micro Integrated Voltage Regulation Cells and Shared Programmable References,” filed Oct. 20, 2023, each of which is incorporated by reference in its entirety. This application also claims the benefit of U.S. Provisional Patent Application No. 63/611,066, titled “Thermal Conducting Structure for Vertically Integrated On-chip Inductor based IVR Chiplets with SoC,” filed Dec. 15, 2023, which is incorporated by reference in its entirety.

### TECHNICAL FIELD

This application relates generally to power and thermal management of an electronic system and/or a circuit package incorporating integrated circuits.

### BACKGROUND

A System on Chip (SoC) consolidates multiple components of a computer, such as a processor, memory, input/output interfaces, and various peripherals, on a substrate. SoCs are widely used in modern electronics, including smartphones, tablets, and embedded systems, where space, power efficiency, and performance are critical. To manage complex power requirements of these components, a Power Management Integrated Circuit (PMIC) is employed. The PMIC is responsible for regulating, distributing, and controlling the power delivered to the SoC's various subsystems. It efficiently manages multiple voltage levels, enabling features like dynamic voltage scaling to conserve energy and ensure the SoC operates within its optimal power and thermal limits. Together, the SoC and PMIC form a highly efficient system capable of handling diverse tasks with minimal power consumption, making them essential in today's compact, high-performance devices. However, the PMIC applied with the SoC may face some issues with consistency among different power rails and stability within a single power rail. Consistency issues arise when different power rails fail to deliver uniform voltage levels or fail to sequence properly, leading to performance variations or even malfunctions in the SoC. This can be caused by mismatched regulation circuitry, differing load demands, or poor coordination between multiple power rails. Stability issues, on the other hand, affect individual power rails where voltage fluctuations, oscillations, or noise occur within a single rail. These problems can cause intermittent failures, timing errors, or degraded performance in the SoC.

Additionally, managing thermal dissipation of the PMIC is challenging, because traditional system designs primarily focus on thermal solutions for processors. Stated another way, the PMIC may lack adequate heat dissipation pathways, resulting in potential thermal buildup. This imbalance affects overall system performance, reliability, and efficiency, especially in system designs for high-current and high-power applications.

### SUMMARY

In accordance with at least some implementations disclosed herein is the realization that an SoC requires consistent and reliable power delivery on its power rails. Each power rail delivers its rail voltage consistently, and different power rails providing the same rail voltage may need to be consistent with one another. Various implementations of this application are directed to methods, systems, devices, and integrated circuits for generating one or more rail voltages to power a plurality of power rails using a configurable power management integrated circuit (PMIC) that applies one or more consolidated reference circuits. The configurable PMIC includes an array of micro-integrated voltage regulator cells. A subset of voltage regulator cells may be selected and grouped to function as a power supply driving a power rail. The selected voltage regulator cells are driven by the same reference circuit In some implementations, the voltage regulator cells of the PMIC are grouped to form a plurality of power supplies, e.g., each of which outputs a programmable rail voltage, and a subset of voltage regulator cells corresponding to each respective power supply is driven by a respective common reference circuit.

Additionally, in accordance with at least some implementations disclosed herein is the realization that an array of micro-integrated voltage regulator cells integrated into a configurable PMIC (e.g., a PMIC chip, an integrated voltage regulator (IVR) chiplet) requires sufficient thermal dissipation to transfer heat from the PMIC to ambient. Various implementations of this application are directed to methods and circuit packages for generating a thermal path (e.g., a thermal via) for vertically mounted chiplets (e.g., PMIC chips, integrated voltage regulator chiplets, and other chiplets with integrated circuits, which encounter heat dissipation challenges) in a circuit package. The thermal path is built on a printed circuit board (PCB) along with solid via(s) and/or heat exchanger(s), thereby effectively improving thermal performance of the vertically mounted integrated voltage regulator chiplets. References herein to a chiplet are equally applicable to a PMIC chip, an integrated voltage regulator chiplet, and other chiplets (e.g., in high-temperature and/or high- power applications) and vice-versa. In some implementations, an integrated voltage regulator chiplet is configured as a PMIC chip.

In one aspect of the application, the circuit package includes a plurality of chiplets. The circuit package further includes a substrate coupled to the plurality of chiplets. The circuit package further includes a processor coupled to the plurality of chiplets through the substrate. The circuit package further includes a PCB coupled to the plurality of chiplets and including a thermal path between a first side and a second side of the PCB. The thermal path is configured to dissipate heat from the plurality of chiplets to ambient.

In another aspect of the application, a method is implemented to provide a circuit package for thermal dissipation. The method includes providing a plurality of chiplets. The method further includes providing a substrate coupled to the plurality of chiplets. The method further includes providing a processor coupled to the plurality of chiplets through the substrate. The method further includes providing a PCB coupled to the plurality of chiplets and including a thermal path between a first side and a second side of the PCB, wherein the thermal path is configured to dissipate heat from the plurality of chiplets to ambient.

These illustrative implementations and implementations are mentioned not to limit or define the disclosure, but to provide examples to aid understanding thereof. Additional implementations are discussed in the Detailed Description, and further description is provided there.

### BRIEF DESCRIPTION OF THE DRAWINGS

For a better understanding of the various described implementations, reference should be made to the Detailed Description below, in conjunction with the following drawings in which like reference numerals refer to corresponding parts throughout the figures.

FIG. 1 is a block diagram of an example electronic system, in accordance with some implementations.

FIGS. 2A and 2B are a top perspective view and a bottom perspective view of an example electronic system including an SoC, in accordance with some implementations, respectively.

FIGS. 3A and 3B are a top perspective view and a bottom perspective view of another example electronic system, in accordance with some implementations, respectively.

FIG. 4A is a high-level block diagram of an example PMIC module, in accordance with some implementations, and FIG. 4B is a detailed block diagram of an example PMIC module, in accordance with some implementations.

FIG. 5 is a schematic diagram of an example voltage regulator cell, in accordance with some implementations.

FIG. 6 is a conceptual diagram illustrating example two voltage regulator cells (also shown in FIG. 4B) for providing a rail voltage V_{RAIL}, in accordance with some implementations.

FIG. 7A is a perspective view of an example PMIC chip including a plurality of inductors coupled in a plurality of voltage regulator cells, in accordance with some implementations.

FIGS. 7B and 7C are two cross sectional views of a portion of the PMIC chip shown in FIG. 7A including two inductors of two voltage regulator cells, in accordance with some implementations.

FIG. 8 is a cross-section view of a circuit package that includes a thermal path, in accordance with some implementations.

FIG. 9A is a cross-section view of an example architecture of the circuit package that includes a thermal path having one or more vias and a thermal conducting layer connecting a plurality of PMIC chips to a printed circuit board (PCB), in accordance with some implementations.

FIG. 9B is a cross-section view of another example architecture of the circuit package that includes a thermal path having a plurality of via groups and a thermal conducting layer connecting a plurality of PMIC chips to a PCB, in accordance with some implementations.

FIGS. 9C-9D are cross-section views of another example architectures of the circuit package 800, each of which includes an additional cooling component compared with the example architectures 900 and 950, respectively, in accordance with some implementations.

FIG. 10A is a cross-section view of another example architecture of the circuit package that includes a thermal path having one or more vias and a metal-solder structure connecting a plurality of PMIC chips to a PCB, in accordance with some implementations.

FIG. 10B is a cross-section view of another example architecture of the circuit package that includes a thermal path having a plurality of via groups and a metal- solder structure connecting a plurality of PMIC chips to a PCB, in accordance with some implementations.

FIG. 11 is a cross-section view of an example architecture of the circuit package 800 that includes a thermal path defining a vacancy that allows a heat exchanger to be coupled to a plurality of PMIC chips, in accordance with some implementations.

FIG. 12 is a cross-section view of an another example architecture of the circuit package that includes a heat exchanger for heat dissipation and a socket for positioning a substrate on a PCB, in accordance with some implementations.

FIG. 13 is a flow diagram of an example method for providing the circuit package, in accordance with some implementations.

Like reference numerals refer to corresponding parts throughout the several views of the drawings.

### DETAILED DESCRIPTION

Reference will now be made in detail to specific implementations, examples of which are illustrated in the accompanying drawings. In the following detailed description, numerous non-limiting specific details are set forth in order to assist in understanding the subject matter presented herein. But it will be apparent to one of ordinary skill in the art that various alternatives may be used without departing from the scope of claims and the subject matter may be practiced without these specific details. For example, it will be apparent to one of ordinary skill in the art that the subject matter presented herein can be implemented on many types of electronic devices with storage capabilities.

In accordance with at least some implementations disclosed herein is the realization that an SoC requires consistent and reliable power delivery on its power rails. Each power rail delivers its rail voltage consistently, and different power rails providing the same rail voltage may need to be consistent with one another. Various implementations of this application are directed to methods, systems, devices, and integrated circuits for generating one or more rail voltages to power a plurality of power rails using a configurable power management integrated circuit (PMIC) that applies one or more consolidated reference circuits. The configurable PMIC includes an array of micro-integrated voltage regulator cells. A subset of voltage regulator cells may be selected and grouped to function as a power supply driving a power rail. The selected voltage regulator cells are driven by the same reference circuit In some implementations, the voltage regulator cells of the PMIC are grouped to form a plurality of power supplies, e.g., each of which outputs a programmable rail voltage, and a subset of voltage regulator cells corresponding to each respective power supply is driven by a respective common reference circuit.

In accordance with at least some implementations disclosed herein is the realization that a challenge of grouping a set of voltage regulator cells is load current balancing (or sharing) among the voltage regulator cells when each voltage regulator cell has a respective regulation control loop. Stated another way, two voltage regulator cells provide different output voltages and experience a load current imbalance, potentially causing a power rail coupled to these two voltage regulator cells to malfunction and permanently damage electronic components powered by the power rail.

To overcome this issue, a reference circuit is shared among a set of voltage regulator cells coupled to the same power rail. An output voltage of each voltage regulator cell tracks a respective reference voltage provided by the shared reference circuit. In some implementations, a digital-to-analog converter (DAC) provides a reference voltage that may drift based on different factors (e.g., locations, manufacturing conditions), even when the DAC is programmed using fixed digital input data. When the DAC is applied within a reference voltage source driving multiple voltage regulator cells coupled to the same power rail, the reference voltage drift jointly for the voltage regulator cells coupled to the same power rail, thereby making these voltage regulator cells perform consistently and stay in balance with one another. In some implementations, an array of DACs is coupled to a reference voltage distribution bus and a switch array, and configured to provide a common voltage reference to a set of voltage regulator cells that output the same rail voltage. Each voltage regulator cell does not have its self-contained DAC, thereby eliminating a current imbalance issue due to differences among self-contained DACs.

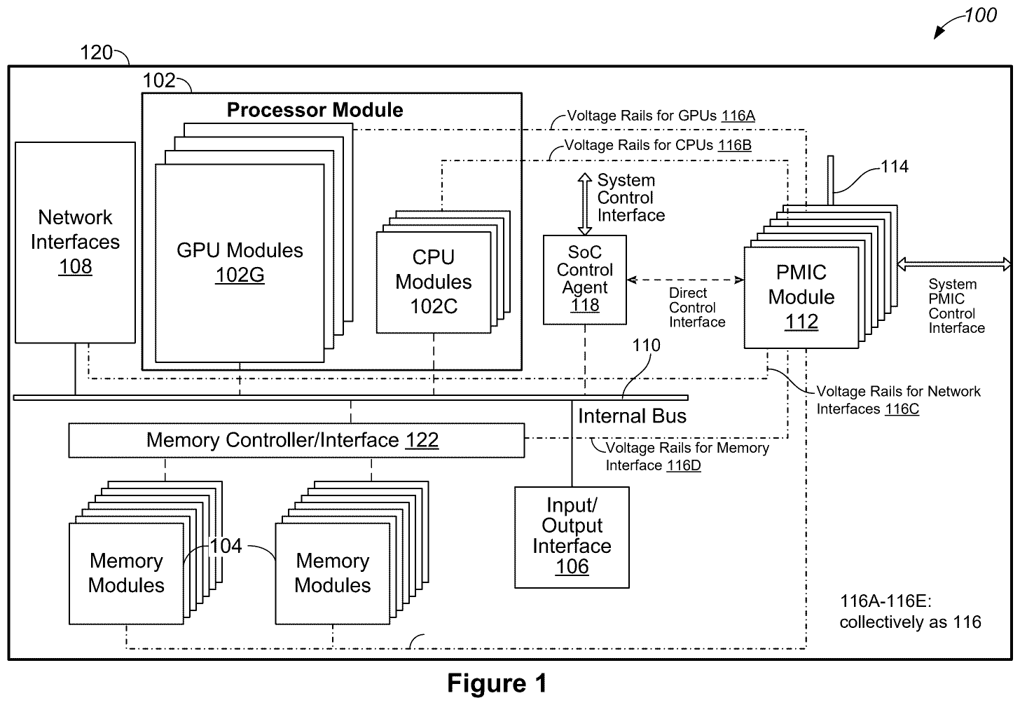

FIG. 1 is a block diagram of an example electronic system 100, in accordance with some implementations. The electronic system 100 includes at least a processor module 102, memory modules 104, an input/output (I/O) interface 106, one or more communication interfaces such as network interfaces 108, and one or more communication buses 110 for interconnecting these components. In some implementations, the I/O interface 106 allows the processor module 102 to communicate with an I/O device (e.g., a keyboard, a mouse or a trackpad). The I/O interface 106 may comply with a data communication bus standard including, but not limited to, universal serial bus (USB) and peripheral component interconnect express (PCIe). In some implementations, the communication bus(es) 110 include circuitry (sometimes called a chipset) that interconnects and controls communications among various system components included in electronic system 100. In some implementations, the electronic system 100 further includes other specialized hardware (e.g., wireless radios, graphics card, sound card, sensors).

In some implementations, the electronic system 100 further includes a PMIC module 112 configured to receive an input supply voltage 114. The PMIC module 112 is configured to modulate the received input supply voltage 114 to desired DC voltage levels, e.g., 5V, 3.3V or 1.8V, as required by various components or circuits (e.g., the processor module 102) within the electronic system 100. For example, the PMIC module 112 is configured to generate the DC voltage levels at a plurality of power rails 116 for providing power to other components (e.g. components 102-110) in the electronic system 100. Examples of the plurality of power rails 116 include, but are not limited to: one or more GPU power rails 116A, one or more CPU power rails 116B, one or more networking power rails 116C, one or more memory interface power rails 116D, and one or more memory module power rails 116E. In some implementations, the PMIC module 112 further includes a layer within a printed circuit board (PCB) or an integrated circuit (IC), and the layer is applied as an input power plane for distributing the input supply voltage 114.

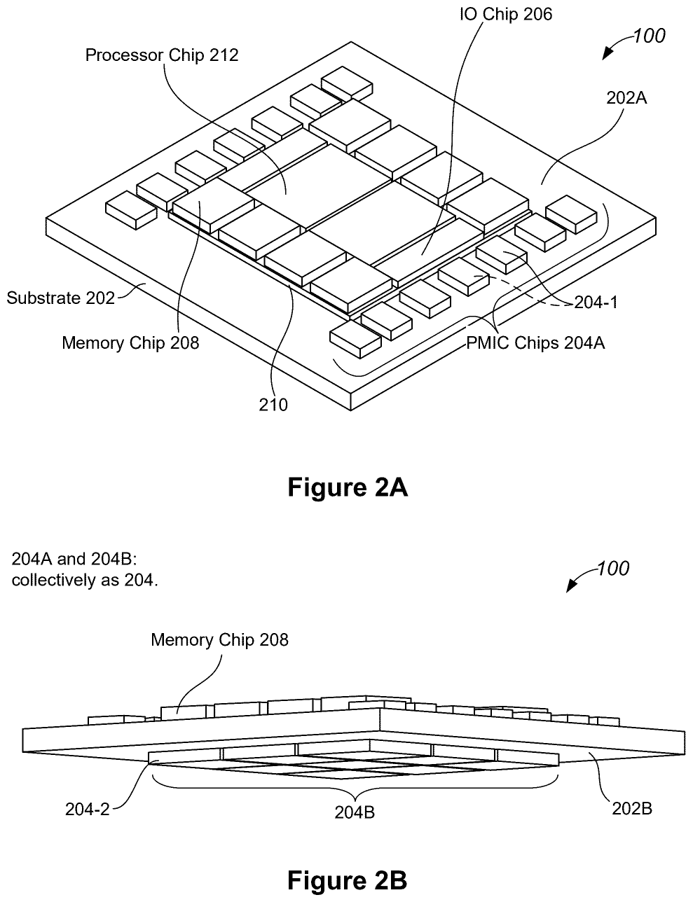

In some implementations, the electronic system 100 corresponds to an SoC 120. Different components of the electronic system 100 may be formed on two or more integrated circuits distributed on two or more chips, which are further assembled on a single substrate (e.g., substrate 202 in FIG. 2A) of the SoC 120. Alternatively, in some implementations, different components of the electronic system 100 are included in an integrated circuit formed on a single substrate of the SoC 120. In an example, the SoC 120 includes one of a silicon substrate, a polymeric substrate, a glass substrate, or a printed circuit board (PCB). Examples of the polymeric substrate include, but are not limited to, polyimide (PI), polyethylene terephthalate (PET), and polydimethylsiloxane (PDMS).

In some implementations, the SoC 120 further includes an SoC control agent 118 that refers to a control mechanism or module within the SoC 120. The SoC control agent 118 is configured to manage operation of different components (e.g., components 102-110) integrated on the SoC 120. More specifically, in some implementations, the SoC control agent 118 is configured to perform one or more of: resource management, inter-component communication, power management, task scheduling, security management, thermal management. For example, the SoC control agent 118 may allocate resources like power, processing time, and memory bandwidth to different components of the SoC 120; manages communication between various components, such as coordinating data transfers between the processor module 102 and peripherals; turn off or put certain components into a low-power state when they are not in use to conserve energy; manage scheduling of different tasks or operations across processing units of the processor module 102 within the SoC 120; implements security features (e.g., using hardware security modules, encryption, and access control); or monitor temperature sensors and adjusts operation (e.g., reducing clock speeds) to prevent overheating. In an example, the SoC control agent 118 includes one or more of: a power controller, a bus controller, and a clock controller. In some implementations, the SoC control agent 118 is implemented on a firmware level, e.g., adjusting system parameters dynamically based on workloads or external conditions.

In some implementations, the processor module 102 includes a plurality of processing units. In some implementations, the processor module 102 includes two or more different types of processing units including a subset of: one or more central processing units (CPUs) 102C, one or more graphics processing units (GPU) 102G, a digital signal processor (DSP), a neural processing unit (NPU) (also called artificial intelligence (AI) accelerator), an image signal processors (ISP), a video processing unit (VPU), an audio processing unit (APU), a secure microcontroller, and a field programmable gate array (FPGA). The CPUs 102C are configured to execute instructions from software (e.g., operating systems, applications). Examples of CPU architecture include, but are not limited to, reduced instruction set computing (RISC) and complex instruction set computing (CIS). The GPUs 102G are configured to render graphics and handle tasks that require parallel processing, such as image processing, video encoding/decoding, and machine learning.

In some implementations, the network interfaces 108 is configured to enable communication between the SoC 120 and external networks, such as local area networks (LANs) or the Internet, and includes both hardware and software components that handle data transmission, reception, and protocol management. The network interfaces 108 may include one or more interfaces for Wi-Fi, Ethernet, and Bluetooth networks, each allowing the electronic system 100 to exchange data with an external source, and participate in networked applications, such as IoT (Internet of Things), mobile communications, or cloud computing.

In some implementations, the memory modules 104 include high-speed random-access memory, such as static random-access memory (SRAM), double data rate (DDR) dynamic random-access memory (DRAM), or other random-access solid state memory devices. In some implementations, the memory modules 104 include non-volatile memory, such as one or more magnetic disk storage devices, optical disk storage devices, flash memory devices, or other non-volatile solid state storage devices. In some implementations, the memory modules 104, or alternatively the non-volatile memory device(s) within the memory modules 104, include a non-transitory computer readable storage medium. In an example, a memory module 104 includes a high bandwidth memory (HBM) configured to provide a data bandwidth greater than a bandwidth threshold to support GPUs 102G. The HBM includes a plurality of memory dies that are stacked vertically on top of each other. In some implementations, the electronic system 100 further includes a memory controller 122 coupled to manage memory access requests for the memory modules 104.

FIGS. 2A and 2B are a top perspective view and a bottom perspective view of an example electronic system 100, in accordance with some implementations, respectively. The electronic system 100 includes an SoC 120 having a substrate 202. The substrate 202 includes a first surface 202A and a second surface 202B that is opposite to the first surface 202A. The substrate 202 may be one of a silicon substrate, a polymeric substrate, a glass substrate, or a PCB. Examples of the polymeric substrate include, but are not limited to, PI, PET, and PDMS. In some implementations, each electronic component of the electronic system 100 corresponds to a region of the substrate 202, and includes a portion of an integrated circuit of the SoC 120. Alternatively, in some implementations, each electronic component of the electronic system 100 includes one or more chips that are mounted onto the substrate 202, e.g., with or without an intermediate support structure 210. In an example, the substrate 202 is made of a polymeric material, and the intermediate support structure 210 is made of silicon and applied to mechanically support a plurality of components (e.g., including an IO chip 206, a memory chip 208, a processor chip 212).

In some implementations not shown, all electronic components included in the electronic system 100 are disposed on the first surface 202A of the substrate 202. Alternatively, in some implementations, a first subset of electronic components of the electronic system 100 are disposed on the first substrate 202A of the substrate 202, and a second subset of electronic components of the electronic system 100 are disposed on the second substrate 202B of the substrate 202. In an example, one or more chips corresponding to a subset of the electronic components 102-108, 118, and 122 are disposed on the second surface 202B. In another example, one or more chips corresponding to the PMIC module 112 are disposed on the second surface 202B.

In some implementations, the PMIC module 112 includes a plurality of distinct PMIC chips 204, which further include a first set of PMIC chips 204A and a second set of PMIC chips 204B. The first set of PMIC chips 204A are disposed on the first surface 202A of the substrate 202, e.g., jointly with all or a subset of remainder components of the SoC 120 distinct form the PMIC module 112. The second set of PMIC chips 204B are disposed on the second surface 202B of the substrate 202. A rail voltage outputted by the first set of PMIC chips 204A is routed on or under the first surface 202A, e.g., by way of a configurable power plane, to access a power rail 116 of the remainder components of the SoC 120. In some implementations, a rail voltage is outputted by the second set of PMIC chips 204B and routed vertically across the substrate 202, from the second surface 202B to the first surface 202A, to access an associated power rail 116 located on or under the first surface 202A, e.g., by way of a configurable power plane.

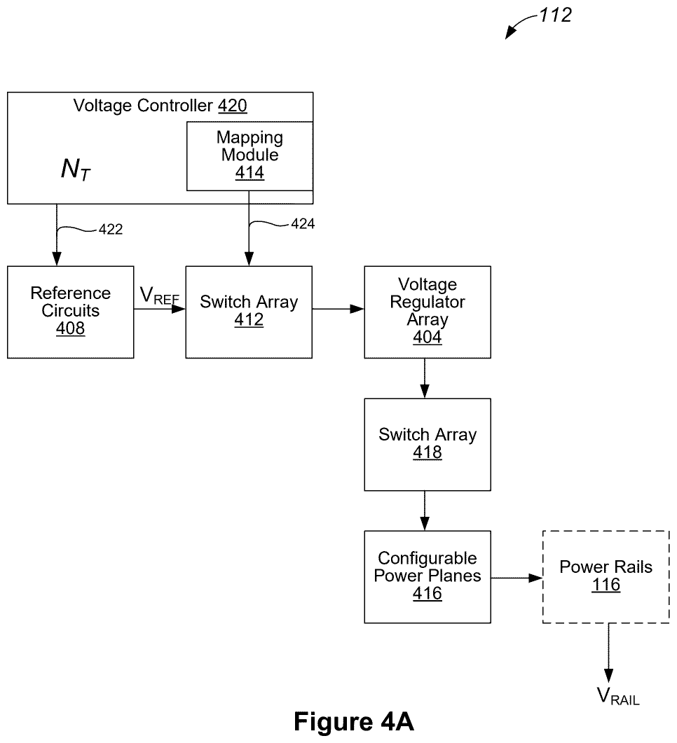

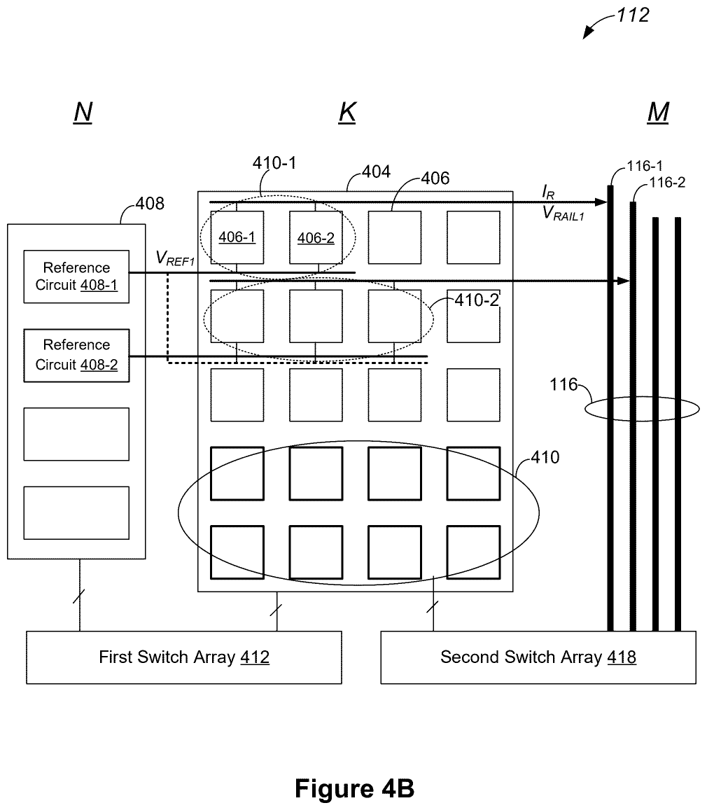

In some implementations, the PMIC module 112 includes a plurality of voltage regulator cells (e.g., voltage regulator cells 406 in FIG. 4B). In an example, a first PMIC chip 204-1 includes a subset of one or more respective voltage regulator cells (e.g., cell 406 in FIG. 4B), and is disposed immediately adjacent to an IO chip 206 including the I/O interface 106, allowing the I/O interface 106 to access a rail voltage provided by the subset of voltage regulator cells of the first PMIC chip 204-1. Alternatively, in some situations, two or more first PMIC chip 204-1 are disposed immediately adjacent to the IO chip 206 to provide the rail voltage to the IO chip 206 jointly. In another example, a memory chip 208 including one of the memory modules 104 is disposed on a location of the first surface 202A, and a second PMIC chip 204-2 is disposed a location of the second surface 202B aligned with (e.g., opposite to) the location of the first surface 202A. The second PMIC chip 204-2 includes a subset of one or more respective voltage regulator cells (e.g., cell 406 in FIG. 4B), and allows the one of the memory modules 104 to access a rail voltage provided by the respective voltage regulator cells vertically. By these means, a component of the SoC 120 may access its associated voltage regulator cell(s) located on a respective PMIC chip 204 that is disposed in proximity to the component without introducing an extended length to access a power rail 116, which helps reduce resistive and capacitive parasitics of the power rail 116 and enhance performance of the SoC 120.

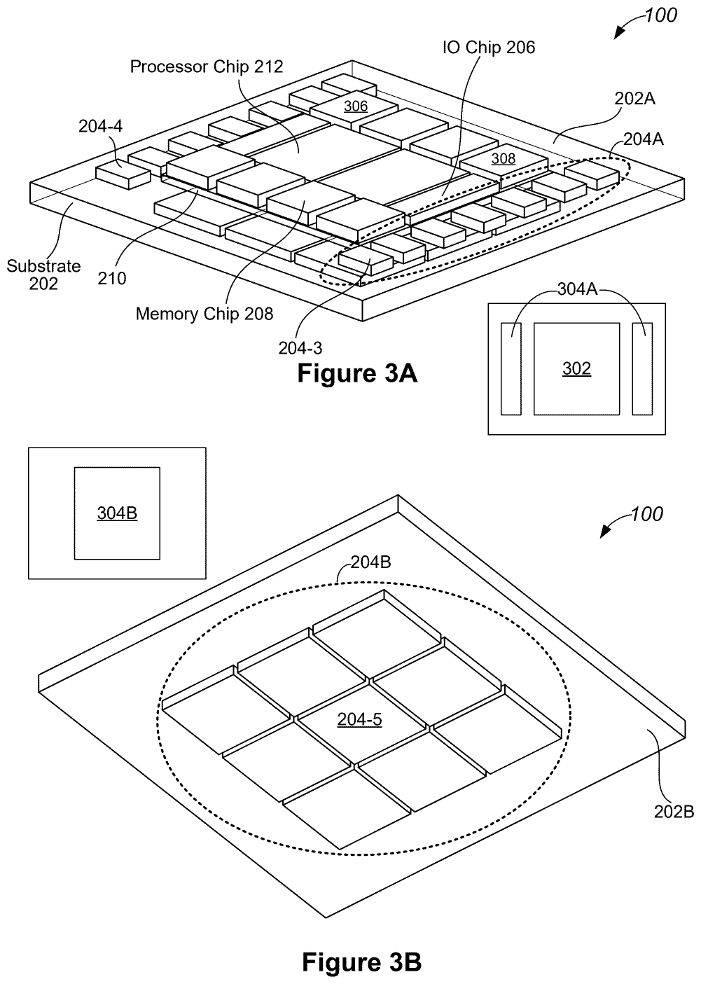

FIGS. 3A and 3B are a top perspective view and a bottom perspective view of another example electronic system 100, in accordance with some implementations, respectively. In some implementations, the first surface 202A of the substrate 202 includes a device region 302 on which a plurality of component chips (e.g., processor chip 212, IO chip 206, memory chips 208) are disposed. One or more first PMIC regions 304A (e.g., two PMIC regions) are located adjacent to the device region 302, and a first set of PMIC chips 204A are disposed on the one or more PMIC regions 304A of the first surface 202A of the substrate 202. For example, two rows of PMIC chips 204A are disposed adjacent to two opposing sides of the device region 302. In another example not shown, four rows of PMIC chips 204A are disposed adjacent to four distinct sides of the device region 302, respectively.

In some implementations not shown, the second surface 202B of the substrate 202 includes an alternative device region on which one or more component chips (e.g., processor chip 212, IO chip 206, memory chips 208) are disposed and one or more PMIC regions on which a second set of PMIC chips 204B are disposed, independently of a chip arrangement of the first surface 202A. Alternatively, in some implementations (FIG. 3B), the second surface 202B of the substrate 202 includes a second PMIC region 304B. Referring to FIG. 3A, the perspective view of the integrated electronic system 100 is depicted from the top angle with a see-through effect (e.g., to see through the substrate 202). In some implementations, the second PMIC region 304B at least partially overlaps the device region 302, allowing a component chip mounted on the device region 302 to access an output of the second PMIC region 304B using a via (e.g., a through silicon via (TSV)).

In some implementations, centers of the second PMIC region 304A and the device region 302 are aligned with one another, i.e., a center of the second PMIC region 304A and a center of the device region 302 are directly opposite to one another on two opposing surfaces 202A and 202B of the substrate 202. Further, in some implementations, sizes of the second PMIC region 304A and the device region 302 are equal to each other. Alternatively, in some implementations, the sizes of the second PMIC region 304A and the device region 302 are different from each other. Alternatively, in some implementations, the second PMIC region 304A and the device region 302 are independent from one another in size and/or in position.

In other words, the PMIC module 112 includes a plurality of voltage regulator cells distributed in a subset of the plurality of PMIC chips 204. Each PMIC chip 204 is located at a respective position on the first surface 202A or the second surface 202B of the substrate 202. In some implementations, the plurality of voltage regulator cells are grouped based on their locations to provide a plurality of rail voltages to a plurality of power rails 116 coupled to different components of the SoC 120. More specifically, in some implementations, each power rail 116 coupled to a component (e.g., CPU chip, GPU chip, memory chip, IO chip) is coupled to a set of voltage regulator cells, which are selected based on their locations with respect to a location of the component. For example, the set of voltage regulator cells are the closest to the respective component in distance compared with a remainder of the voltage regulator cells, thereby controlling associated resistive and capacitive parasitics. In another example, the set of voltage regulator cells, which coupled to the respective component, provides the lowest parasitic level. Among two voltage regulator cells having equal distances form the respective component, a voltage regulator cell located on the first surface 202A is selected over a voltage regulator cell located on the second surface 202B. In some implementations, a voltage regulator cell located on the first surface 202A and having a larger distance from the respective component is selected over a voltage regulator cell located on the second surface 202B and having a smaller distance from the respective component.

In some implementations, the PMIC module 112 further includes a plurality of reference circuits (e.g., circuit 408 in FIGS. 4A and 4B). The plurality of reference circuits may be formed on the same PMIC chip 204 or distributed on two or more PMIC chips 204. For example, each PMIC region 304A or 304B includes at least one PMIC chip 204 (e.g., chips 204-3, 204-4, and 204-5) dedicated to providing one or more reference circuits. In another example, all of the plurality of reference circuits used within the voltage regulator cells of the PMIC module 112 are consolidated on a single PMIC chip (e.g., chip 204-5).

Alternatively, in some implementations, the plurality of reference circuits used with the voltage regulator cells of the PMIC module 112 are provided by a single chip 306 or distributed among a plurality of chips (e.g., chips 306 and 308), which are mounted on, or integrated in, the device region 302.

FIG. 4A is a high-level block diagram of an example PMIC module 112, in accordance with some implementations, and FIG. 4B is a detailed block diagram of an example PMIC module 112, in accordance with some implementations. The PMIC module 112 includes, or is coupled to, a plurality of power rails 116 configured to provide one or more rail voltages V_{RAIL}. The PMIC module 112 further includes an array 404 of voltage regulator cells 406 and a plurality of reference circuits 408. The plurality of reference circuits 408 are coupled to, but distinct from, the array 404 of voltage regulator cells 406. The array 404 of voltage regulator cells 406 is coupled to the plurality of power rails 116, and configured to provide a plurality of voltage regulator sets 410. Each voltage regulator set 410 is configured to output a respective rail voltage V_{RAIL} to a respective power rail 116. Each of the plurality of reference circuits 408 is shared by, and configured to provide a respective reference voltage V_{REF} to, one or more respective voltage regulator cells 406 of a respective voltage regulator set 410. The respective voltage regulator set 410 is configured to generate the respective rail voltage V_{RAIL} based on the respective reference voltage V_{REF}.

Stated another way, some implementations of this application include a PMIC module 112 that has an array 404 of voltage regulator cells 406, a plurality of voltage references 408 that are selectable and programmable, and distribution circuits and buses that are selectable. Different numbers of voltage regulator cells 406 may be grouped together to form a voltage regulator set 410 for outputting a rail voltage V_{RAIL} (also called a power supply voltage). The array 404 of voltage regulator cells 406 may be grouped to form a single voltage regulator set 410 or a plurality of power regulator sets 410, thereby providing a single rail voltage V_{RAIL} or multiple rail voltages V_{RAIL}. In some implementations, the PMIC module 112 provides a plurality of rail voltages V_{RAIL} correspond to a plurality of distinct voltage regulator sets 410, and each voltage regulator set 410 includes a respective number of voltage regulator cells 406, independently of other voltage regulator set(s) 410. For each voltage regulator set 410, outputs of the respective voltage regulator cells 406 are electrically coupled (e.g., shortened) to one another and further to a respective power rail 116. In some implementations, a voltage regulator set 410 is configured to output a variable rail voltage V_{RAIL}, e.g., to track a respective reference voltage V_{REF}.

In some implementations, the PMIC module 112 includes, or is coupled to, a single substrate (e.g., substrate 202 in FIGS. 2A and 2B). The array 404 of voltage regulator cells 406 and the plurality of reference circuits 408 are disposed on the substrate 202, separately from one another. In some implementations, the array 404 of voltage regulator cells 406 and the plurality of reference circuits 408 correspond to different sets of PMIC chips 204 disposed on PMIC regions 304A and 304B (FIGS. 3A and 3B) of the substrate 202. Alternatively, in some implementations, the array 404 of voltage regulator cells 406 is distributed in PMIC chips 204 disposed on the PMIC regions 304A and 304B of the substrate 202, and the plurality of reference circuits 408 correspond to chips (e.g., chip 306 or 308 in FIG. 3A) disposed on a device region 302 (FIG. 3A) of the substrate 202.

Referring to FIG. 4B, in some implementations, the plurality of power rails 116 include a first number M of power rails 116, and the plurality of reference circuits 408 include a second number N of reference circuits 408. The second number N is equal to or less than the first number M. Further, in some implementations, each reference circuit 408 and a respective power rail 116 is uniquely associated with each other, and the respective reference circuit 408 is configured to provide the respective reference voltage V_{REF} to the respective voltage regulator cell set 410 assigned to generate the rail voltage V_{RAIL} for the power rail 116. A number of voltage regulator cells 406 in the respective voltage regulator cell set 410 may be varied.

In some implementations, rail voltages V_{RAIL} of two power rails 116-1 and 116-2 are equal to each other, and each power rail 116 maintains a consistent voltage. It is required that voltage regulator cells 406 contributing to each respective power rail 116-1 or 116-2 be driven by the same respective reference circuit 408. Further, in some implementations, two voltage regulator sets 410-1 and 410-2 corresponding to the two power rails 116-1 and 116-2 are coupled to two distinct reference circuits 408-1 and 408-2. Alternatively, in some implementations, the two voltage regulator sets 410-1 and 410-2 corresponding to the two power rails 116-1 and 116-2 are coupled to the same reference circuit 408 (e.g., 408-1). As such, the second number N of the reference circuits 408 is equal to or less than the first number M of the power rails 116.

In some implementations, the plurality of power rails 116 include a first number M of power rails 116, and the plurality of reference circuits 408 include a second number N of reference circuits 408. The array 404 of voltage regulator cells 406 includes a third number K of voltage regulator cells 406. The second number N is equal to or less than (≤) the third number K, and the first number M is equal to or less than (≤) the third number K.

In some implementations, the PMIC module 112 includes a first switch array 412 (e.g., having the second number N of rows and the third number K of columns, or the second number N of columns and the third number K of rows). For example, rows of the first switch array 412 are electrically coupled to the second number N of reference circuits 408, and columns of the first switch array 412 are electrically coupled to the third number K of voltage regulator cells 406 of the array 404. Each row-column cross section of the first switch array 412 includes a switch component configured to control coupling of a respective reference circuit 408 and a respective voltage regulator cell 406. For each voltage regulator set 410 (e.g., set 410-1 in FIG. 4B), a respective set of switch components of the first switch array 412 are enabled to couple the respective reference circuit 408 (e.g., circuit 408- 1) to the one or more respective voltage regulator cells 406 (e.g., cells 406-1 and 406-2). Note that, in some implementations, lines connecting the reference circuits 408-1 and 408-2 directly to the voltage regulator cells 406 in the voltage regulator sets 410-1 and 410-2 may not correspond to interconnects and are drawn in FIG. 4B merely for illustrative purposes.

Referring back to FIG. 4A, in some implementations, the PMIC module 112 further includes a mapping module 414 coupled to the first switch array 412. The mapping module 414 is configured to control the switch components of the first switch array 412 to group the voltage regulator cells 406 to form the plurality of voltage regulator sets 410. More specifically, the mapping module 414 is configured to determine whether to enable or disable each of the switch components of the first switch array 412.

In some implementations, the PMIC module 112 further includes a plurality of configurable power planes 416 embedded in a module substrate of the PMIC module 112 or a substrate 202 to which the PMIC module 112 is mounted. Each of the plurality of power rails 116 is electrically coupled to a respective power plane 416, and extends to one or more electrical components (e.g., modules 102-108) to provide a respective rail voltage V_{RAIL} to these components. Each output of voltage regulator cells 406 of a respective voltage regulator set 410 is also electrically coupled to the respective power plane 416, providing the power voltage V_{RAIL} to the respective power plane 416.

Further, referring to FIG. 4B, in some implementations, the PMIC module 112 includes a second switch array 418 (e.g., having the first number M of rows and the third number K of columns, or the first number M of columns and the third number K of rows). For example, rows of the first switch array 412 are electrically coupled to the first number M of power rails 116 or configurable power planes 416, and columns of the second switch array 418 are electrically coupled to outputs of the third number K of voltage regulator cells 406 of the array 404. Each row-column cross section of the second switch array 418 includes a switch component configured to control coupling a respective voltage regulator cell 406 to a respective configurable power plane 416 or to a respective power rail 116. For each voltage regulator set 410 (e.g., set 410-1 in FIG. 4B), a respective set of switch components of the first switch array 412 are enabled to couple the one or more respective voltage regulator cells 406 (e.g., cells 406-1 and 406-2) to the a respective configurable power plane 416 or to the respective power rail 116 (e.g., rail 116-1). Additionally, in some implementations, the second switch array 418 and the first switch array 412 are integrated in a single switch array.

Note that, in some implementations, lines connecting the power rails 116-1 and 116-2 directly to the voltage regulator cells 406 in the voltage regulator sets 410-1 and 410-2 may not correspond to interconnects and are drawn in FIG. 4B merely for illustrative purposes.

In some implementations, the plurality of voltage regulator sets 410 include a first voltage regulator set 410-1 that is configured to output a first rail voltage V_{RAIL1} (e.g., 1.2V, 0.8V) to a first power rail 116-1, and the first rail voltage is equal to a first reference voltage V_{REF1} provided by a first reference circuit 408-1. Stated another way, an output voltage level of each voltage regulator set 410 is set by its associated reference voltage, and the voltage regulator set 410 is configured to track its associated reference voltage provided by a respective reference circuit 408.

Referring back to FIG. 4A, in some implementations, the PMIC module 112 further includes a voltage controller 420 coupled to the plurality of reference circuits 408. The voltage controller 420 is configured to generate a digital control signal 422 based on the first rail voltage associated with the first power rail 116-1 and provide the digital control signal 422 to the first reference circuit 408-1 defining the first reference voltage V_{REF1}. The first power rail 116-1 extends to one or more electrical components (e.g., modules 102-108) to provide the first rail voltage to these components. Characteristics of the first power rail 116-1 (e.g., rail current, rail voltage) are determined based on operation of the one or more electrical components. The first reference voltage of the first reference circuit 408-1 is further determined and set based on the characteristics of the first power rail 116-1. In some implementations, the plurality of reference circuits 408 are identical to one another. The digital control signal 422 determines magnitudes of the reference voltages V_{REF} outputted by the plurality of reference circuits 408. Conversely, in some implementations, at least two of the plurality of reference circuits 408 are different from one another. In an example, each reference circuit 408 includes a digital-to-analog converter (DAC).

Additionally, in some implementations, the first voltage regulator set 410-1 further includes a target number N_{T} (e.g., 2) of voltage regulator cells 406 and is configured to deliver up to a predefined rail current I_{RAIL}, to the first power rail 116-1. The target number N_{T} is determined based on the predefined rail current I_{RAIL}, e.g., equal to the predefined rail current I_{RAIL}, divided by a regulator current I_{VGC} that is deliverable by each voltage regulator cell 406. Additionally, in some implementations, the PMIC module 112 further includes a voltage controller 420 coupled to the array 404 of voltage regulator cells 406. The voltage controller 420 is configured to determine the target number N_{T} based on the predefined rail current I_{RAIL}, associated with the first power rail 116-1, generate one or more select signals 424 based on the target number N_{T}, and provide the one or more select signals 424 to the array 404 of voltage regulator cells 406 to select the target number N_{T} of voltage regulator cells 406 (e.g., cells 406-1 and 406-2) of the first voltage regulator 116-1. In some implementations, the mapping module 414 is part of the voltage controller 420.

In some implementations, voltage regulator cells 406 in the array 404 of voltage regulator cells 406 are identical to each other. An output voltage of each voltage regulator cell 406 is determined based on a respective reference voltage V_{REF} received by the respective voltage regulator cell 406. The higher a rail current I_{RAIL} of a power rail 116, the larger the target number N_{T} of the voltage regulator cells 406 grouped to drive the power rail 116.

Conversely, in some implementations, at least two voltage regulator cells 406 in the array 404 of voltage regulator cells 406 are different from one another. For example, an output voltage of each voltage regulator cell 406 is determined based on a respective reference voltage V_{REF} received by the respective voltage regulator cell 406. The two voltage regulator cells 406 may have different driving capabilities (e.g., different regulator currents). Different numbers of the two voltage regulator cells 406 may be selected and combined based on a rail current I_{RAIL} associated with a power rail 116 and regulator currents I_{VGC} of the two voltage regulator cells 406.

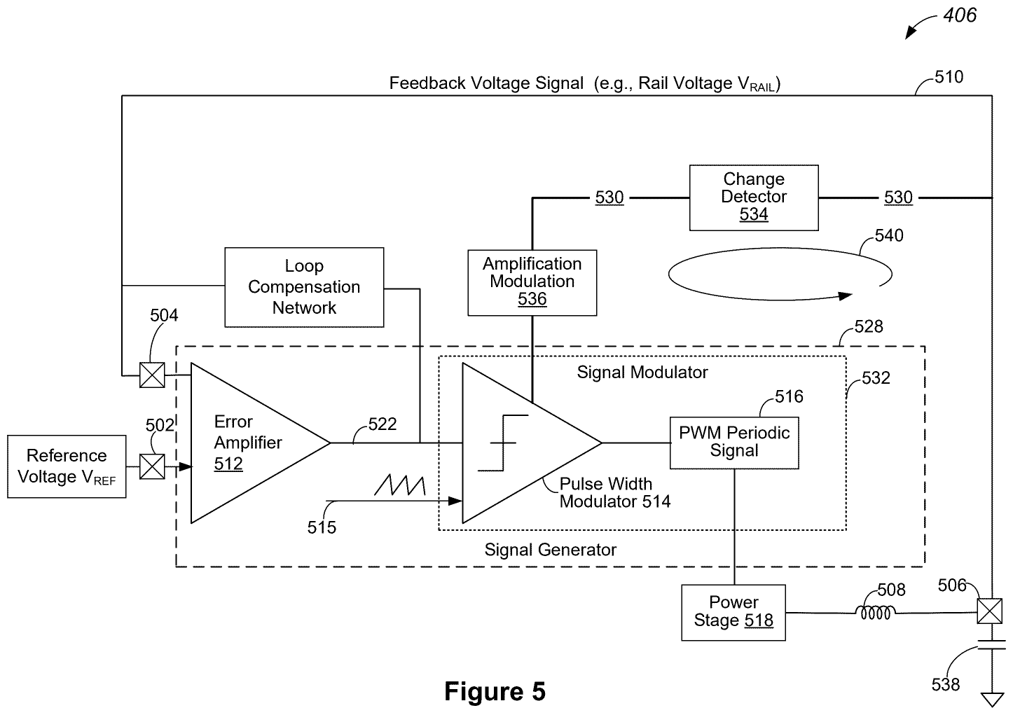

FIG. 5 is a schematic diagram of an example voltage regulator cell 406, in accordance with some implementations. In some implementations, the voltage regulator cell 406 includes an input reference interface 502 for receiving a target reference voltage V_{REF}, an input signal interface 504 for receiving an input signal (e.g., rail voltage V_{RAIL}), an output interface 506 for providing a rail voltage V_{RAIL} to a power rail (e.g., power rail 116-1 in FIG. 4B), a first feedback path 510 coupling the output interface 506 of the voltage regulator cell 406 to the input signal interface 504 of the voltage regulator cell 406, and an inductor 508 electrically coupled between the input signal interface 504 and the output interface 506.

In some implementations, the voltage regulator cell 406 includes an error amplifier 512, a pulse width modulator 514, a power stage 518, and the feedback path 510. The error amplifier 512 is configured to receive a reference voltage V_{REF} and a rail voltage V_{RAIL} and generate an amplified difference signal 522. The pulse width modulator 514 is coupled to the error amplifier 512 configured to generate a pulse width modulated (PWM) periodic signal 516 having a pulse width and a feature frequency f. In an example, the pulse width modulator 514 includes a comparator, and receives an input signal 515 having a Sawtooth waveform or a triangular waveform. The pulse width modulator 514 is coupled to the error amplifier 512 and configured to modulate the pulse width of the input signal 515. The power stage 518 is coupled to the pulse width modulator 514 and configured to generate the rail voltage V_{RAIL} based on the PWM periodic signal 516. In an example, the power stage 518 includes one or more power field effect transistors (FETs). The feedback path 510 is configured to couple an output of the power stage 518 to an input of the error amplifier 512, e.g., jointly with an inductor 508.

In some implementations, the voltage regulator cell 406 includes a signal generator 528, a power stage 518, and a first feedback path 510 coupling an output of the power stage to a signal input of the signal generator 528. The signal generator 528 is configured to receive a target reference voltage V_{REF} and a rail voltage V_{RAIL} and generate a PWM periodic signal 516 having a target pulse width. The power stage 518 is coupled to the signal generator 528 and configured to generate the rail voltage based on the PWM periodic signal 516 having the target pulse width. Further, in some implementations, in the voltage regulator cell 406, a second feedback path 530 couples the output of the power stage 518 to a signal modulator 532 of the signal generator 528. The second feedback path 530 is configured to pull the rail voltage V_{RAIL} back to the target reference voltage V_{REF} when the rail voltage V_{RAIL} deviates from the target reference voltage V_{REF} at a deviation rate higher than a characteristic circuit rate of the voltage regulator cell 406.

Further, in some implementations, the second feedback path 530 further includes a change detector 534 and an amplification and modulation circuit 536. The change detector 534 is coupled to the output of the power stage 518, and configured to detect the rail voltage V_{RAIL} deviating from the target reference voltage V_{REF} at the deviation rate. The amplification and modulation circuit 536 is coupled to the change detector 534 and the signal modulator 532, and configured to adjust a pulse width of the PWM periodic signal 516 in real-time, when the rail voltage V_{RAIL} deviates from the target reference voltage V_{REF} at the deviation rate. In other words, in some implementations, the change detector 534 is configured to sense fast voltage changes in the feedback voltage signal in the first feedback path 510 (e.g., corresponding to fast voltage changes in an output of the voltage regulation cell 406). The change detector 534 generates a modulation signal to modulate the signal modulator 532, thereby preventing an output of the voltage regulator cell 406 from deviating from the reference voltage V_{REF}.

State another way, in some implementations, the voltage regulation cell 406 is implemented based on a regulation control loop using one or more of a power stage 518, an integrated on-chip inductor 508, and a feedback voltage signal (e.g., carrying rail voltage V_{RAIL} in a first feedback path 510). The regulation control loop tracks a difference between voltage feedback signal and the selected reference voltage V_{REF}, and generates pulse width modulated signals (e.g., PWM periodic signal 516) driving the power stage 518. The output of the power stage 518 may drive an integrated on-chip inductor 508.

In some implementations, an inductor 508 and an output filter capacitor 538 forms an output filter. The output filter may be part of, or external to, a respective voltage regulator cell 406. The output filter may partially belong to a respective voltage regulator cell 406. The output filter capacitor 538 may be embedded in a GPU or CPU package substrate, a substrate of the SoC 120 (e.g., substrate 202), or a processor chip 212 (FIG. 2A). In some implementations, for a voltage regulator set 410, output terminals of on-chip inductors 508 of voltage regulator cells 406 of the voltage regulator set 410 correspond to the output interface 506, and are coupled via interconnects to an output filter capacitor 538, which may be external to the voltage regulator cells 406. Stated another way, the voltage regulator cells 406 of the voltage regulator set 410 share, and is routed separately via the interconnects to, a common output filter capacitor 538. Further, in some implementations, the feedback voltage signal carried by the feedback path 510 is connected to the output filter capacitor via the interconnects extending external to the voltage regulator cells 406.

Additionally, in some implementations, a regulation control mechanism of a voltage regulator cell 406 employs dual control loops including the regulation control loop and a transient modulation loop 540. The regulation control loop is based on the first feedback path 510, and configured to modulate the PWM periodic signal 516 based on an error signal (e.g., amplified difference signal 522) generated by integrating a difference between the reference voltage V_{REF} and the feedback voltage signal. In some implementations, the regulation control loop integrates a difference between the reference voltage V_{REF} and the feedback voltage signal, and includes a signal modulator 532, which is shared with the transient modulation loop 540. The amplified difference signal 522 reflects integration of the difference between the reference voltage V_{REF} and the feedback voltage signal, and is applied to modulate the PWM periodic signal 516 and generate a rail voltage V_{RAIL} to be outputted at the output interface 506 of the voltage regulator cell 406. The rail voltage V_{RAIL} settles at the associated reference voltage V_{REF}. Additionally, the transient modulation loop 540 is configured to modulate the PWM periodic signal 516 based on detection of transient characteristics of the feedback voltage signal (e.g., the rail voltage V_{REF}).

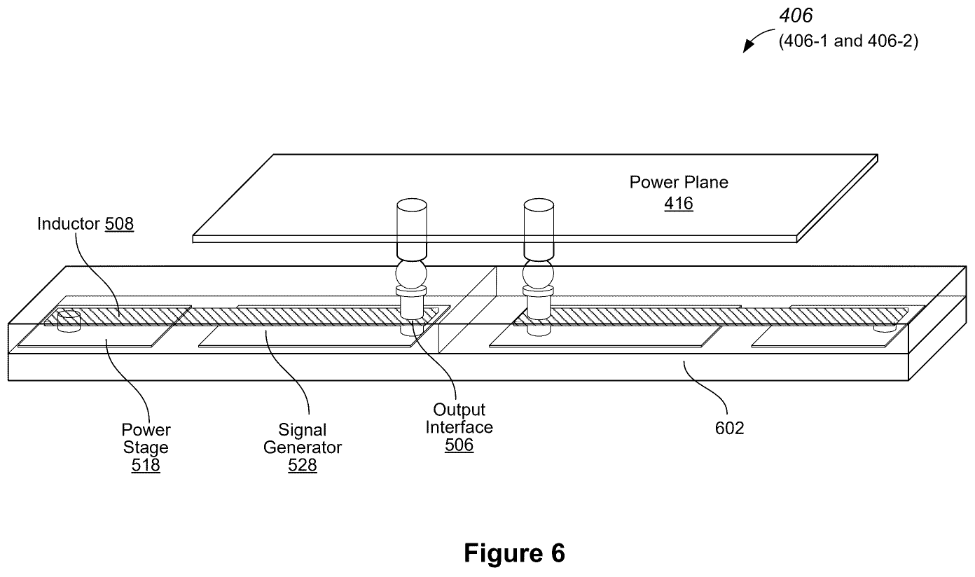

FIG. 6 is a conceptual diagram illustrating example two voltage regulator cells 406-1 and 406-2 (also shown in FIG. 4B) for providing a rail voltage V_{RAIL}, in accordance with some implementations. Each of the two voltage regulator cells 406-1 and 406-2 includes a respective inductor 508 electrically coupled to an output interface 506 of the respective voltage regulator cell 406. In some implementations, for each voltage regulator cell 406-1 or 406-2, the respective inductor 508 is integrated on chip, e.g., monolithically formed on a respective PMIC chip 204. In some implementations, a configurable power plane 416 is embedded in a module substrate of a PMIC module 112 or a substrate 202 of the SoC 120 to which a PMIC module 112 is mounted. The two voltage regulator cells 406-1 and 406- 2 may be formed on a common chip substrate 602 or on two distinct chip substrates 602. The output interfaces 506 of the two voltage regulator cells 406-1 and 406-2 are electrically coupled to the power plane 416, which is further coupled to a power rail 116 (not shown on FIG. 6).

In some implementations, the inductor 508 is integrated on the cell substrate 602, e.g., above the signal generator 528, the power stage 518, and/or any other circuits 408, 412, 418, or 420 of the PMIC module 112. An input terminal of the inductor 508 is coupled to an output of the power stage 518, e.g., using a via, a metallic layer, a solder ball, a redistribution layer (RDL), or a combination thereof. In an example, an output terminal of the inductor 508 corresponds to an output of the inductor 508, and is connected to an interconnect that couples the inductor 508 to a bump or a solder ball of the PMIC module 112. The bump or solder ball is applied to electrically couple the PMIC module 112 to other electrical components (e.g., components 102-108) of an SoC 120. In some implementations, each of two terminals of the inductor 508 includes a respective interconnect made of a via, a metallic layer, an RDL, or a combination thereof, and is configured to provide a Kelvin sensing point.

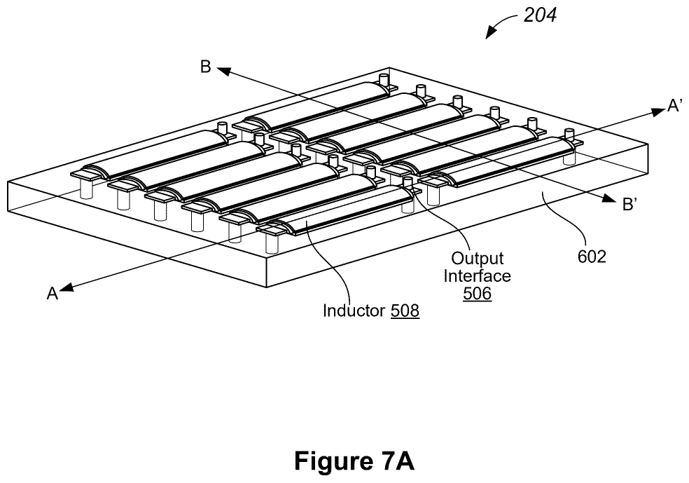

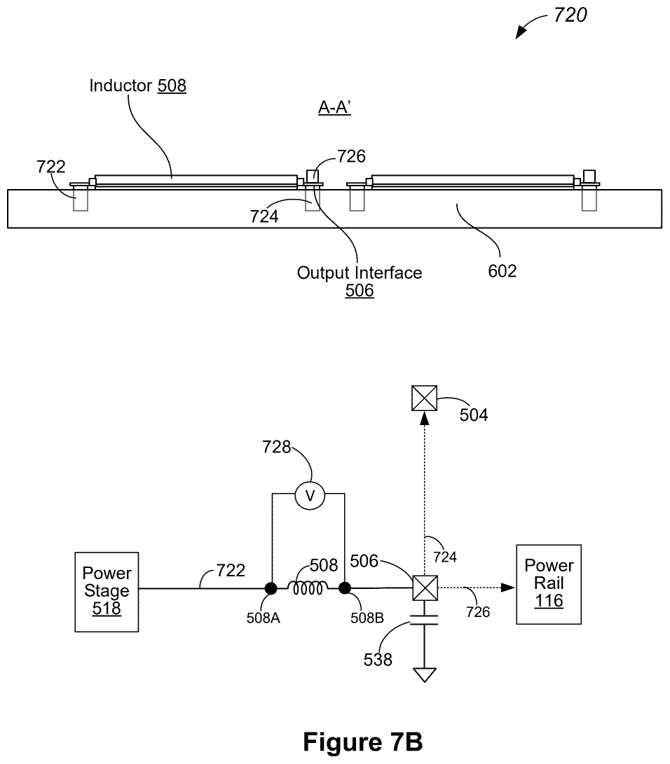

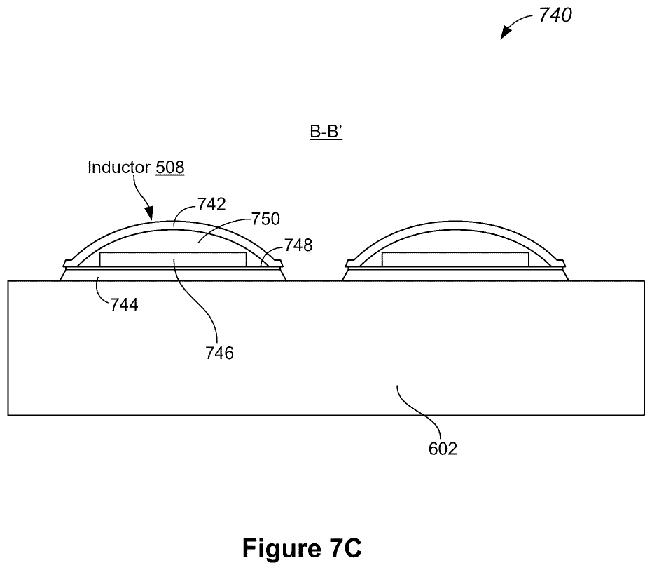

FIG. 7A is a perspective view of an example PMIC chip 204 including a plurality of inductors 508 coupled in a plurality of voltage regulator cells 406, in accordance with some implementations, and FIGS. 7B and 7C are two cross sectional views 720 and 740 of a portion of the PMIC chip 204 shown in FIG. 7A including two inductors 508 of two voltage regulator cells 406, in accordance with some implementations. The PMIC chip 204 has a chip substrate 602 and includes twelve voltage regulator cells 406 formed monolithically on a top surface of the chip substrate 602. Each voltage regulator cell 406 includes a respective inductor 508 integrated on the top surface of the chip substrate 602. Stated another way, the voltage regulator cells 406 (e.g., transistors and metal interconnects) may be formed on the cell substrate 602 and partially underneath the inductor 508. The PMIC chip 204 includes two cross sections AA′ and BB′ that are perpendicular to one another and to the top surface of the chip substrate 602. The cross section AA′ is shown in FIG. 7B, and part of the cross section BB′ is shown in FIG. 7C.

Referring to FIG. 7B, in some implementations, an inductor 508 includes three vias 722, 724, and 726. A first via 722 is coupled between an output a power stage 518) of a respective voltage regulator cell 406 to an input terminal 508A of the inductor 508, driving current toward the inductor 508. In some implementations, a second via 724 is coupled between an output terminal 508B of the respective inductor 508. The output terminal 508B of the respective inductor 508 corresponds to an output port 506 of the voltage regulator cell 406. Alternatively, in some implementations, the second via 724 is coupled between the output terminal 508B of the respective inductor 508 and an input signal interface 504 (FIG. 5). A third via 726 is coupled between the output terminal 508B of the inductor 508 and a power rail 116 powering other components (e.g., components 102-108 in FIG. 1) of an SoC 120, providing current and power to enable operations of the other components of the SoC 120. In some implementations, the third via 726 couples the output terminal 508B of the inductor 508 to the power rail 116 via a configurable power plane 416 (FIG. 6). In some implementations, the third via 726 is vertically aligned with the second via 724. In some implementations not shown, the third via 726 is laterally shifted (i.e., not vertically aligned) with respect to the second via 724.

In some implementations, the first via 722 and the second via 724 enable Kelvin connections for sensing a current passing a conduction trace of the inductor 508. A current sensing circuit 728 is coupled to the input terminals 508A and the output terminal 508B of the inductor 508, and configured to measure a voltage drop on the inductor 508. Given that a resistance of the inductor 508 is known, the voltage drop is applied to determine a current passing through the inductor 508.

In some implementations, each of two terminals 508A and 508B of the inductor 508 includes a respective interconnect made of a via, a metallic layer, an RDL, or a combination thereof. The respective interconnect forms a Kelvin connection, which may be coupled to a current sensing circuit associated with the voltage regulator cell 406 for sensing an inductor current running through the inductor 508. In some implementations, a distance between Kelvin connections of each voltage regulator cell 406 is substantially uniform in the array 404 of voltage regulator cells 406 (e.g., in FIG. 7A). For each voltage regulator set 410, current balancing among different voltage regulator cells 406 is enabled using a single shared reference circuit 408.

Referring to FIG. 7C, in some implementations, the inductor 508 is formed on top of the cell substrate 602 (e.g. a silicon substrate), and include at least two laminated magnetic thin film layers 742 and 744 wrapping around a conductor 746. The inductor 508 further includes an insulation film layer 748 and a dielectric filling structure 750. The two laminated magnetic thin film layers 742 and 744 are electrically isolated from the conductor 746 by the insulation film layer 748 and a dielectric filling structure 750. In some implementations, there is no gap in an enclosure formed by the two laminated magnetic thin film layers 742 and 744. Conversely, in some implementations, there is a gap in the enclosure formed by the two laminated magnetic thin film layers 742 and 744. Further, in some implementations, each of the two laminated magnetic thin film layers 742 and 744 includes a stack of alternating magnetic thin films and dielectric thin films.

Thermal VIAs for Vertical Integration of Integrated Voltage Regulators with SoC

An array (e.g., 404 in FIG. 4B) of micro-integrated voltage regulator cells (e.g., 406 in FIG. 4B) in an integrated voltage regulator (IVR) chiplet of a PMIC module (e.g., 112 in FIG. 1) requires sufficient thermal dissipation to transfer heat from the PMIC module to ambient (e.g., air). As described here, various implementations of this application are directed to methods and circuit packages for generating a thermal path (e.g., a thermal via) for vertically mounted integrated voltage regulator chiplets (e.g., 406 in FIG. 4B) in a circuit package. The thermal path is built on a printed circuit board (PCB) along with solid via(s) and/or heat exchanger(s), thereby effectively improving thermal performance of the vertically mounted integrated voltage regulator chiplets. In some implementations, an integrated voltage regulator (IVR) chiplet is configured as a PMIC chip (e.g., the first PMIC chip 204-1, the second PMIC chip 204-2 in reference to FIGS. 2A-2B).

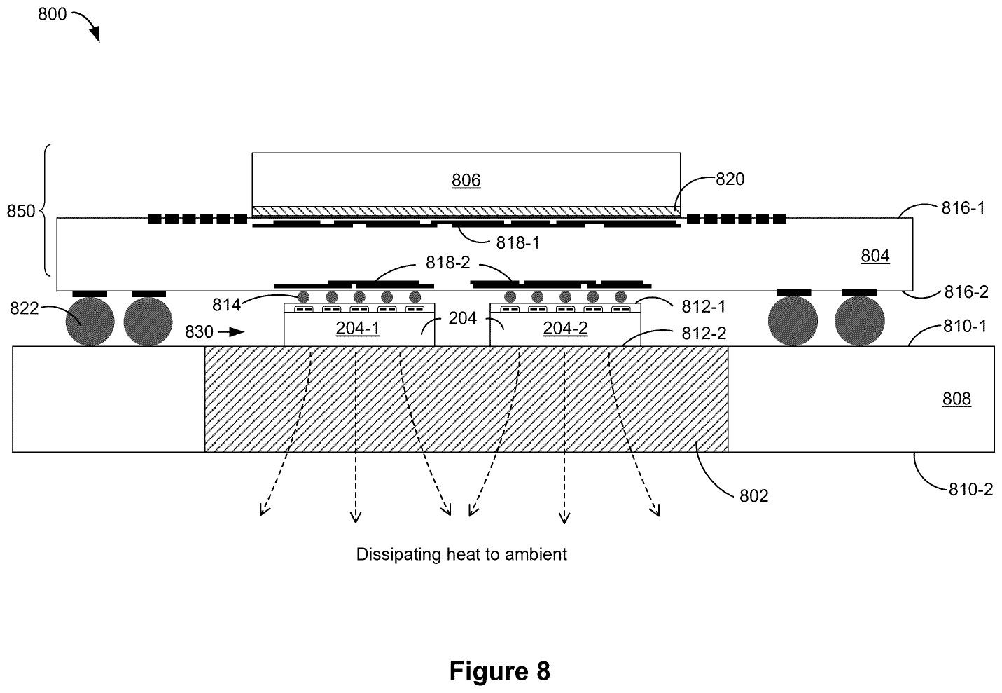

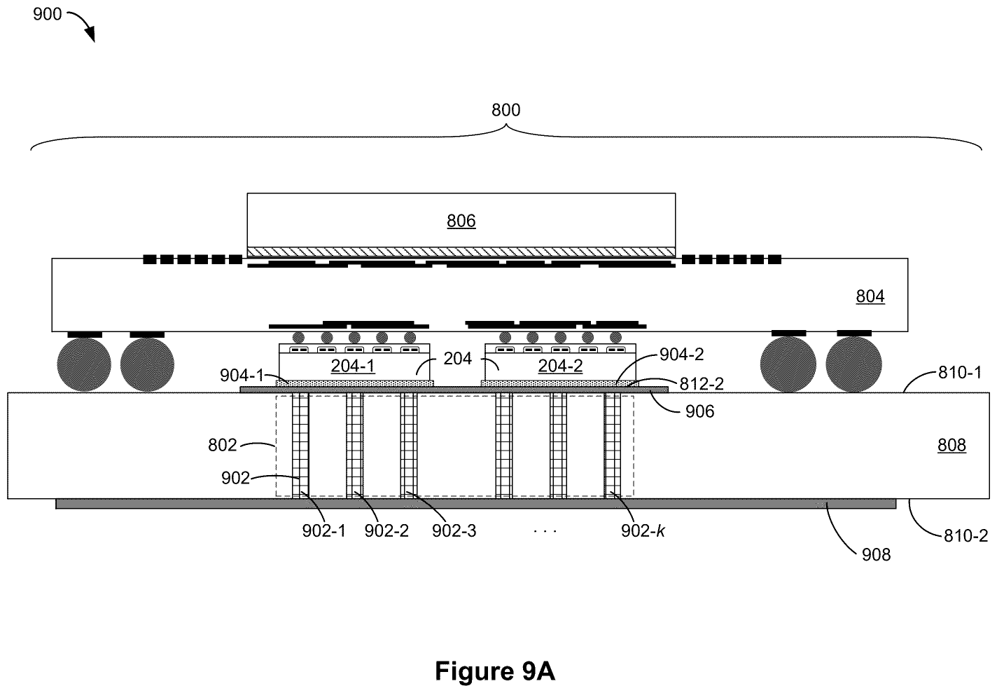

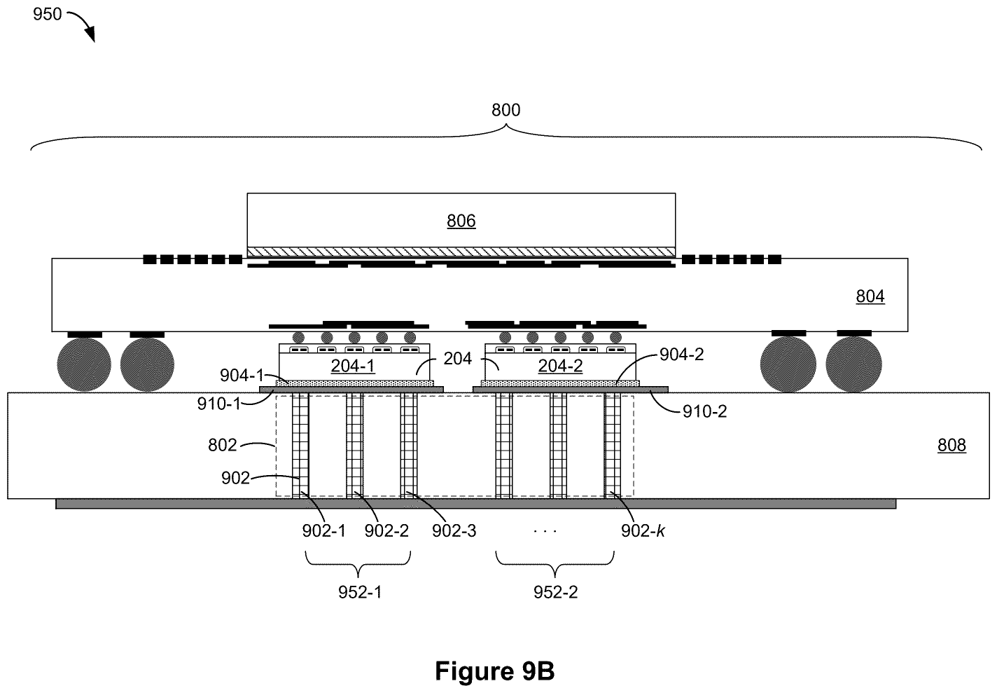

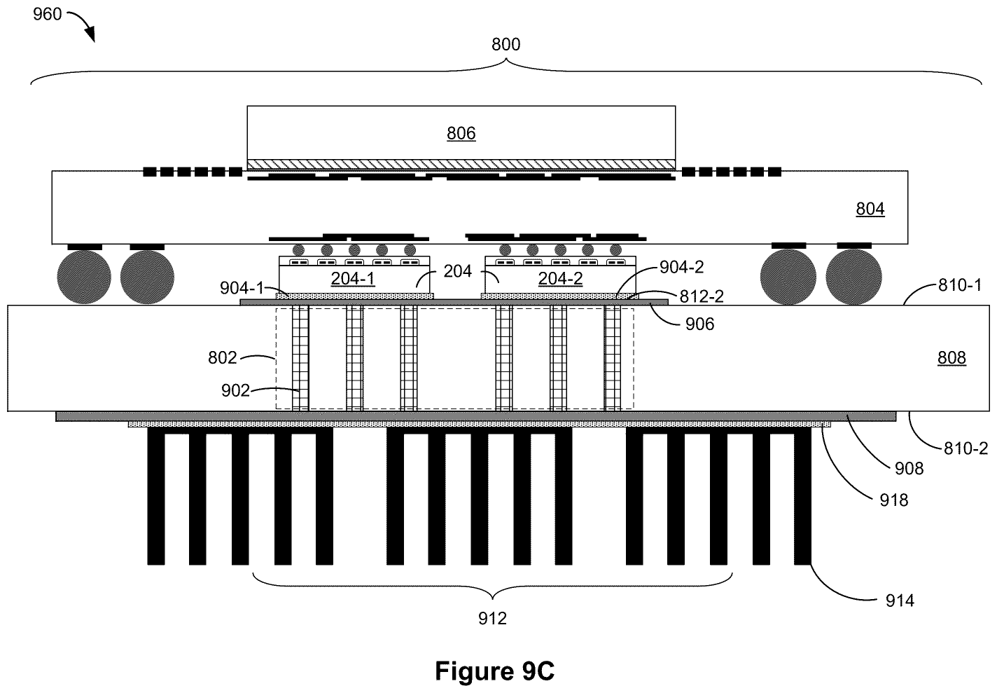

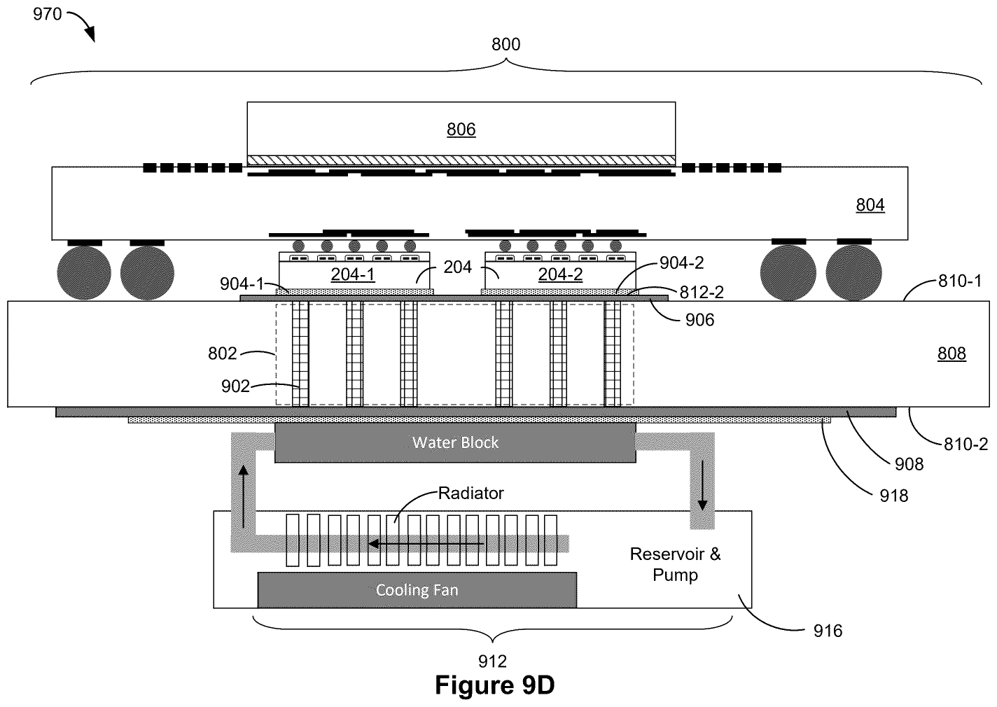

FIG. 8 is a cross-section view of a circuit package 800 that includes a thermal path 802 (e.g., a thermal via), in accordance with some implementations, some of which are described below with reference to FIGS. 9A to 13. The circuit package 800 includes a plurality of PMIC chips 204 (e.g., the first PMIC chip 204-1 and the second PMIC chip 204-2 in reference to FIGS. 2A-2B). Each PMIC chip of plurality of PMIC chips 204 includes a plurality of voltage regulator cells 406 (e.g., respective voltage regulator cells 406- 1 and 406-2 in FIG. 4B). The circuit package 800 further includes a substrate 804 coupled to the plurality of PMIC chips 204 (e.g., the first PMIC chip 204-1 and the second PMIC chip 204-2). The circuit package 800 further includes a processor 806 coupled to the plurality of PMIC chips 204 through the substrate 804. The circuit package 800 further includes a printed circuit board (PCB) 808 coupled to the plurality of PMIC chips 204 and including the thermal path 802 (e.g., a thermal via) between a first side 810-1 and a second side 810-2 of the PCB 808. In some implementations, when the substrate 804 is mounted on the PCB 808, the plurality of PMIC chips 204 is in an enclosed space 830 with insufficient air flows. The thermal path 802 is configured to dissipate heat from the plurality of PMIC chips 204 to ambient (e.g., air). In some implementations, the thermal path 802 extends (e.g., penetrates) from the first side 810-1 of the PCB 810 to the second side 810-2 of the PCB 810. In some implementations, referring to FIGS. 8-13, the plurality of PMIC chips 204 (e.g., the first PMIC chip 204-1 and the second PMIC chip 204-2) are disposed (e.g., vertically mounted) on the same surface (e.g., the first side 810-1 of the PCB 808).

In some implementations, the plurality of voltage regulator cells 406 are configured as a n times m array, where n and m are integers and a number of the voltage regulator cells is greater than two. For example, referring to the array 404 of voltage regulator cells 406 in FIG. 4B, the plurality of voltage regulator cells 406 are arranged in a 5 by 4 array. In some implementations, the plurality of voltage regulator cells 406 are identical to each other. For example, the plurality of voltage regulator cells 406 (e.g., 406-1 and 406-2) have the same driving capabilities (e.g., same regulator currents I_{VGC} in response to a reference voltage V_{REF}). In some implementations, at least two voltage regulator cells of the plurality of voltage regulator cells 406 are different from one another. For example, a respective voltage regulator cell (e.g., 406-1) has a different driving capability compared with another respective voltage regulator cell (e.g., 406-2) (e.g., different regulator currents I_{VGC} in response to a reference voltage V_{REF}).

In some implementations, referring to FIGS. 4B, the plurality of voltage regulator cells 406 are configured to provide a plurality of voltage regulator sets 410, and each voltage regulator set is configured to output a respective rail voltage V_{RAIL}. In some implementations, a plurality of inductors 508 (e.g., integrated on-chip inductors in reference to FIG. 7A) are coupled in the plurality of voltage regulator cells 406. In some implementations, the plurality of voltage regulator cells 406 are micro-integrated voltage regulator (micro-IVR) cells. A micro-IVR cell is a compact voltage regulator implemented as a single chip in one package including components such as control circuitries, transistors, and protective features.

In some implementations, the plurality of PMIC chips 204 include a front side 812-1 and a back side 812-2. The front side 812-1 of the plurality of PMIC chips 204 is electrically coupled to the substrate 804 via solder balls 814 (e.g., solder bumps). The back side 812-2 of the plurality of PMIC chips 204 is coupled to the PCB 810 via thermal and/or electrical conducting layer(s).

In some implementations, the substrate 804 includes a first metal interconnect 818-1 on a first side 816-1 of the substrate 804 and a second metal interconnect 818-2 on a second side 816-2 of the substrate 804. The first and second metal interconnects 818-1 and 818-2 of the substrate 804 are electrically coupled. Moreover, the first metal interconnect 818-1 of the substrate 804 is electrically coupled to the processor 806 for transmitting signals. The second metal interconnect 818-2 of the substrate 804 is electrically coupled to the plurality of PMIC chips 204 via the solder balls 814 and the front side 812-1 of the plurality of PMIC chips 204. In some implementations, the second metal interconnect 818-2 of the substrate 804 is electrically coupled to the PCB 808 via solder balls 822 (e.g., solder bumps). In some implementations, the substrate 804 is a flip chip-ball grid array (FC-BGA) substrate (e.g., for high-frequency and/or high-power applications). In some implementations, the substrate 804 includes an organic material (e.g., epoxy). In some implementations, the substrate includes build-up layers of epoxy, metal layer(s), vias, and core layers. In some implementations, the substrate includes embedded silicon capacitors.

In some implementations, the processor 806 includes a signal contact 820 on a side of the processor 806. The processor 806 is electrically coupled to the substrate 804 via the signal contact 820 of the processor 806 and the first metal interconnect 818-1 of the substrate 804. In some implementations, the processor 806 is configured to exchange signals with the plurality of PMIC chips 204. In some implementations, the processor 806 is configured as a processor chip 212 (see FIG. 2A). In some implementations, the processor 806 includes a system-on-chip (SoC). The SoC integrates different components (e.g., CPUs, signal processing chips, digital/analog converters, interfaces, etc.) into a single integrated circuit for combining functionality, efficiency, and compactness. In some implementations, the processor 806 includes an artificial intelligence (AI) processor configured to process computations related to machine learning, deep learning, and/or other neural networks for AI applications.

In some implementations, the circuit package 800 is assembled using

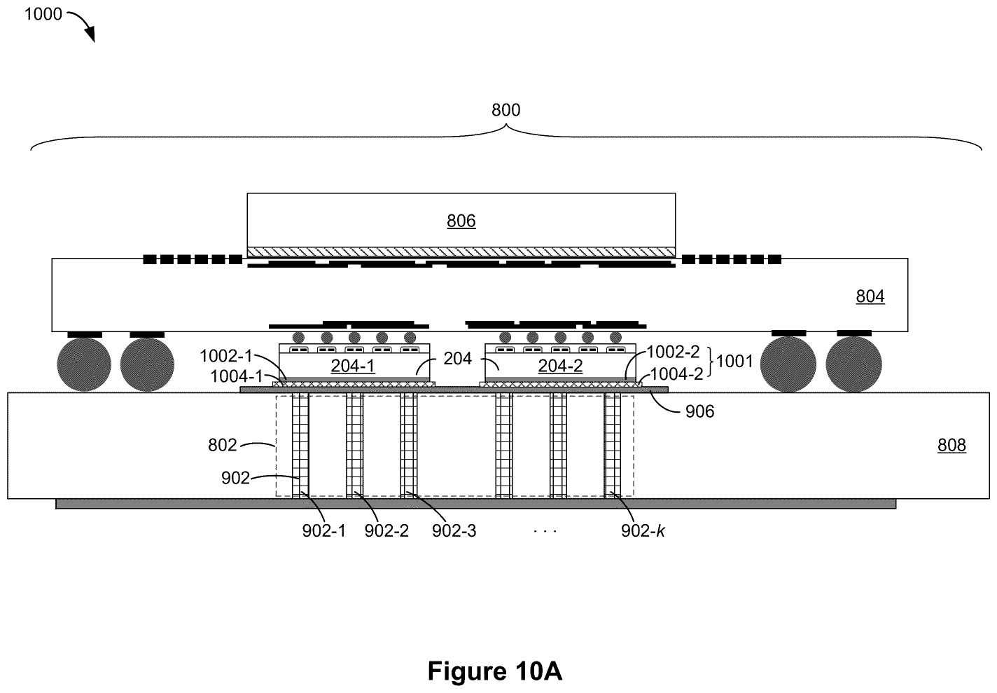

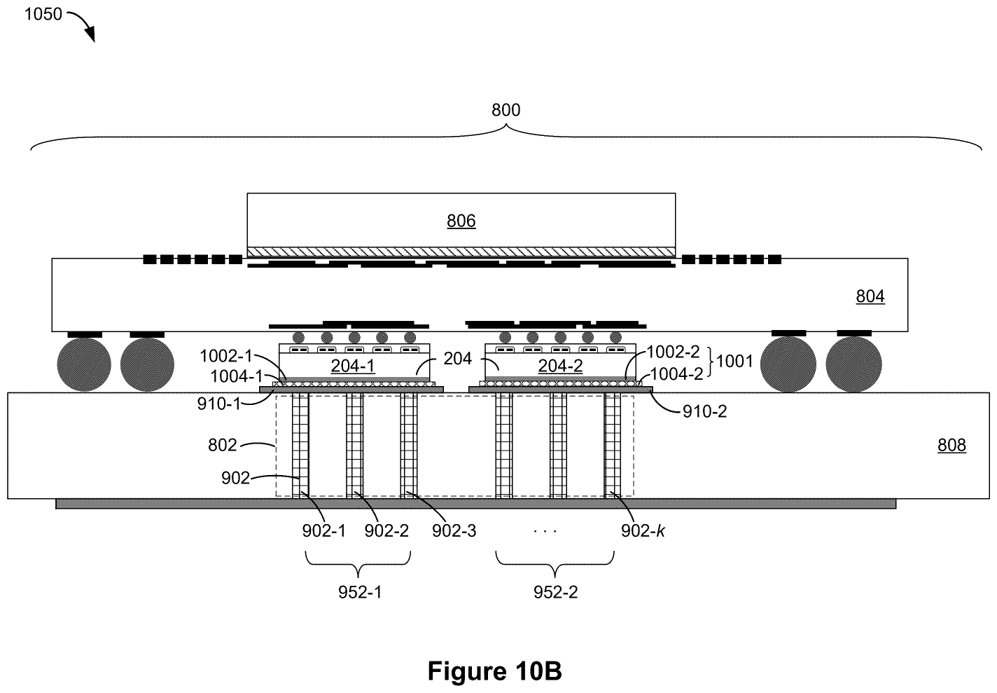

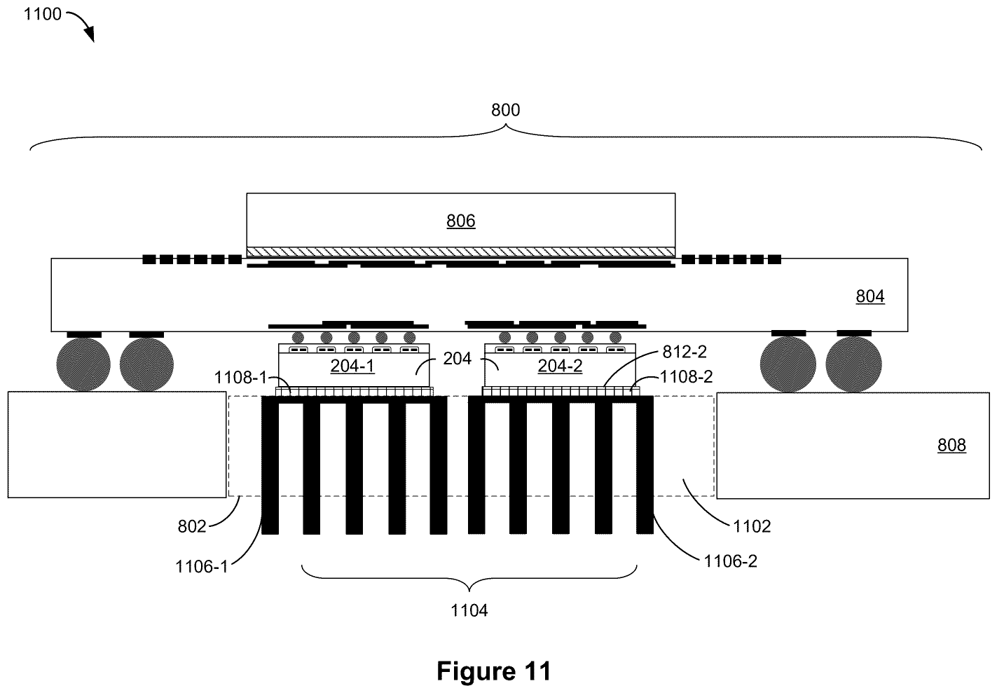

components including the plurality of PMIC chips 204, the substrate 804, the processor 806, and the PCB 808. The processor 806 is mounted, through flip-chip bonding in a reflow process, on the substrate 804 to connect the signal contact 820 of the processor 806 to the first metal interconnect 818-1 of the substrate 804, forming an integrated structure 850. In some implementations, the processor 806 is mounted on the substrate 804 through wire- bonding, soldering, direct die attach, surface mount technology, or other technique(s). The plurality of PMIC chips 204 are mounted on the integrated structure 850 through flip-chip bonding via the solder balls 814 in another reflow process to connect the front side 812-1 of the plurality of PMIC chips 204 to the second metal interconnect 818-2 of the substrate 804. The combination of the integrated structure 850 and the plurality of PMIC chips 204 is mounted on the PCB 808 via the solder balls 822, thermal conducting layer(s) (see 904 in FIGS. 9A and 9B), and/or electrical conducting layer(s) (see 1001 in FIGS. 10A and 10B) through a PCB assembly process. Alternatively, in some implementations, the plurality of PMIC chips 204 are mounted on a heat exchanger (see 1104 in FIG. 11) rather than directly on the PCB 808.

FIG. 9A is a cross-section view of an example architecture 900 of the circuit package 800 that includes the thermal path 802 (e.g., a thermal via) having one or more vias (e.g., 902-1, 902-2, etc.) and a first thermal conducting layer 904 connecting the plurality of PMIC chips 204 to the PCB 808, in accordance with some implementations. In the example architecture 900, the PCB 808 includes a first metal plate 906 disposed on the first side 810-1 of the PCB 808 and a second metal plate 908 disposed on the second side 810-2 of the PCB 808. In particular, the second metal plate 908 provides a large contact surface on the second side 810-2 of the PCB 808 for enhancing heat dissipation (e.g., in a situation where a form factor of the circuit package 800 is small). The thermal path 802 (e.g., a thermal via) includes the solid via 902 connecting the first metal plate 906 and the second metal plate 908 of the PCB 808. The PCB 808 is coupled to the plurality of PMIC chips 204 through the first metal plate 906 of the PCB 808. In some implementations, the first and second metal plates 906 and 908 are configured to enhance heat conduction and transfer heat from the first side 810-1 of the PCB and to the second sides 810-2 of the PCB through the thermal path 802. In some implementations, the first and second metal plates 906 and 908 are patterned during PCB manufacturing.

In some implementations, the solid via 902 in the example architecture 900 enhances thermal performance of the PCB 808. In particular, the solid via 902 facilitates heat transfer between the first and second sides 810-1 and 810-2 of the PCB 808, thereby effectively dissipating heat from the plurality of PMIC chips 204 to ambient. Moreover, the solid via 902 improves thermal management in high-power or high-temperature applications associated with the plurality of PMIC chips 204 and/or the processor 806. In some implementations, the solid via 902 enhances electrical performance of the PCB 808. In particular, the solid via 902, when filled with conductive material(s), minimizes resistance compared to other types of vias (e.g., plated-through holes). Moreover, the solid via 902 improves high-current applications associated with the plurality of PMIC chips 204 and/or the processor 806. In some implementations, the solid via 902 reduces parasitic inductance and resistance, thereby improving performance in high-speed applications (e.g., high- frequency circuitries associated with the processor 806). In some implementations, the solid via 902 enhances mechanical performance the PCB 808. In particular, the solid via 902 improves mechanical stress of the PCB 808 resulting from thermal cycling or physical deformation, thereby increasing durability for the PCB 808.

In some implementations, the solid via 902 in the example architecture 900 includes a conductive material for ensuring a robust electrical connection. In some implementations, the conductive material includes a metal material (e.g., copper, silver, gold, or other type). In some implementations,, the conductive material includes a conductive proxy (e.g., silver, gold, or carbon particles in a polymer matrix). In some implementations, during manufacturing of the PCB 808, the solid vias 902 is planarized to create a smooth surface on the first side 810-1 of the PCB 808 for depositing the first metal plate 906.

In some implementations, the solid via 902 in the example architecture 900 includes one or more vias (e.g., vias 902-1, 902-2, 903-3, . . . , 902-k, where k is an integer greater than one). The one or more vias are configured to enhance heat transfer from the plurality of PMIC chips 204 to ambient. In particular, the one or more vias (e.g., vias 902-1, 902-2, 903-3, . . . , 902-k) create pathways to dissipate heat from a plurality of hotspots distributed on the back side 812-2 of the plurality of PMIC chips 204. Moreover, providing more than one vias enables heat to dissipate more evenly across the PCB 808. In some implementations, the one or more vias (e.g., vias 902-1, 902-2, 903-3, . . . , 902-k) provides a design flexibility for the PCB 808 to meet specifications and requirements of the circuit package 800. For example, parameters (e.g., number of vias, size/diameter of vias, via placement, etc.) are finely tuned to improve heat transfer requirements and balance with PCB routing requirements. In some implementations, a diameter of each via of the one or more vias (e.g., vias 902-1, 902-2, 903-3, . . . , 902-k) ranges from approximately 0.8 mm to approximately 3.2 mm.

In some implementations, the circuit package 800 includes the first thermal conducting layer 904 (e.g., respective thermal conducting layers 904-1 and 904-2) disposed between the first metal plate 906 of the PCB 808 and the plurality of PMIC chips 204 (e.g., the first PMIC chip 204-1 and the second PMIC chip 204-2). In particular, the first thermal conducting layer 904 is configured to act as a mechanical buffer and a thermal conductor for the plurality of PMIC chips 204. For example, the first thermal conducting layer 904 acts as a cushion between the first metal plate 906 of the PCB 808 and the plurality of PMIC chips 204 to absorb and compensate mechanical stress resulting from thermal expansion and/or vibration (e.g., in high-temperature and/or high-current applications). Moreover, the first thermal conducting layer 904 is configured to release stress between the plurality of PMIC chips 204 and the PCB 808. In another example, the first thermal conducting layer 904 acts as a thermal conductor to spread heat evenly across the plurality of PMIC chips 204 to prevent overheating at their hotspots. In some implementations, the first thermal conducting layer 904 is a thermal interface material (TIM) layer. The TIM layer has a high thermal conductivity for efficient heat transfer. Moreover, the TIM layer accommodates to irregular surface textures or profiles (e.g., on the back side 812-2 of the plurality of PMIC chips 204) and provides contact between imperfectly aligned surfaces (e.g., between the back side 812-2 of plurality of PMIC chips 204 and the first metal plate 906 of the PCB 808). In some implementations, the first thermal conducting layer 904 includes at least one of the group consisting of epoxy, gap filler gel(s), curable compound(s), thermal tape(s), grease(s), and phase change material(s). In some implementations, a selection of material(s) for the first thermal conducting layer 904 depends on specifications of the circuit package 800, including electrical requirements, thermal requirements, curing requirements, and operating temperatures.

FIG. 9B is a cross-section view of another example architecture 950 of the circuit package 800 that includes the thermal path 802 (e.g., a thermal via) having a plurality of via groups 952 and the first thermal conducting layer 904 connecting the plurality of PMIC chips 204 to the PCB 808, in accordance with some implementations. In the example architecture 950, the first metal plate 906 of the PCB 808 includes a plurality of metal plates 910 (e.g., respective metal plates 910-1 and 910-2). Each of the plurality of metal plates (e.g., 910-1) of the PCB 808 is electrically coupled to a respective PMIC chip (e.g., 204-1) through a respective thermal conducting layer (e.g., 904-1). The solid via 902 includes a plurality of via groups 952 (e.g., respective via groups 952-1 and 952-2). Each via group (e.g., 952-1) has a plurality of vias (e.g., 902-1, 902-2, and 902-3) and is coupled to a respective PMIC chip (e.g., 204-1) through a respective metal plate (e.g., 910-1).

In some implementations, the plurality of metal plates 910 (e.g., 910-1 and 910-2) are discrete and not physically coupled on the first side 810-1 of the PCB 808. The discrete plurality of metal plates 910 (e.g., 910-1 and 910-2) are implemented to improve heat spreading in conjunction with placement of vias within the plurality of via groups 952. In some implementations, the plurality of metal plates 910 (e.g., 910-1 and 910-2) of the PCB 808 include distinct geometries from one another.

FIGS. 9C-9D are cross-section views of another example architectures 960 and 970 of the circuit package 800, each of which includes an additional cooling component compared with the example architectures 900 and 950, respectively, in accordance with some implementations. In some implementations, the first metal plate 906 of the PCB 808 includes a plurality of metal plates (e.g., 910 in FIG. 9B).

In the example architecture 960, the circuit package 800 includes a first heat exchanger 912 coupled to the second metal plate 908 of the PCB 808. In particular, the surface area of the second metal plate 908 is sufficiently large enough to accommodate the first heat exchanger 912. In some implementations, the first heat exchanger 912 of the example architecture 960 includes a first plurality of heat sinks 914 configured to actively dissipate heat (e.g., using fans or liquids) from the second metal plate 908 to ambient, thereby maximizing thermal management with greater reliability and longer lifespan. Additionally, the first plurality of heat sinks 914 increases surface area for heat dissipation and is capable of dissipating heat for high-power or heat-intensive components (e.g., high-power applications associated with the plurality of PMIC chips 204 and the processor 806). In some implementations, a selection (e.g., models, types, etc.) of the first plurality of heat sinks 914 depends on specifications of the circuit package 800, including electrical requirements, thermal requirements, curing requirements, and operating temperatures.

In the example architecture 970, the circuit package 800 also includes a first heat exchanger 912 coupled to the second metal plate 908 of the PCB 808. Similarly, the surface area of the second metal plate 908 is sufficiently large enough to accommodate the first heat exchanger 912. In some implementations, the first heat exchanger 912 of the example architecture 970 includes a liquid-cooled component 916 (e.g., a reservoir/pump combination) having a reservoir and a pump. The liquid-cooled component 916 also have a reactor, a water block, and a cooling fan. The reservoir is configured to hold coolant and provide a reserve supply to ensure continuous flow through the liquid-cooled component 916. The pump is configured to circulate the coolant through the liquid-cooled component 916 and maintain a consistent flow. The radiator, which has metal fins and tubes, is configured to remove heat from the coolant. The water block is configured to transfer heat from the second metal plate 908 to the coolant. The cooling fan, which is mounted on or near the radiator, is configured to dissipate heat from the coolant into ambient. Additionally, in some implementations, compared with the first plurality of heat sinks 914, the liquid-cooled component 916 is more effective at absorbing and transferring heat (e.g., with largely increased thermal conductivity), provides more consistent cooling performance by using coolant, and is available for a more compact design (e.g., mounted in a constrained space). In some implementations, a selection (e.g., models, types, etc.) of the liquid-cooled component 916 depends on specifications of the circuit package 800, including electrical requirements, thermal requirements, curing requirements, and operating temperatures.

In some implementations, as shown in FIGS. 9C-9D, the first heat exchanger 912 is coupled to the second metal plate 908 of the PCB 808 via a second thermal conducting layer 918. In some implementations, the second thermal conducting layer 918 is a TIM layer. As discussed above, the TIM layer has a high thermal conductivity for efficient heat transfer. In some implementations, the second thermal conducting layer 918 includes at least one of the group consisting of epoxy, gap filler gel(s), curable compound(s), thermal tape(s), grease(s), and phase change material(s). In some implementations, a selection of material(s) for the second thermal conducting layer 918 depends on specifications of the circuit package 800, including electrical requirements, thermal requirements, curing requirements, and operating temperatures.

FIG. 10A is a cross-section view of another example architecture 1000 of the circuit package 800 that includes the thermal path 802 (e.g., a thermal via) having the one or more vias (e.g., 902-1, 902-2, etc.) and a metal-solder structure 1001 connecting the plurality of PMIC chips 204 to the PCB 808, in accordance with some implementations. In some implementations, the plurality of PMIC chips 204 include a metallization layer 1002 (e.g., respective metallization layer 1002-1 and 1002-2). The metallization layer 1002 is part of the metal-solder structure 1001. In some implementations, the circuit package 800 includes a solder layer 1004 (e.g., respective solder layer 1004-1 and 1004-2) disposed between the first metal plate 906 and the metallization layer 1002 (e.g., respective metallization layer 1002-1 and 1002-2) of the plurality of PMIC chips 204 (e.g., the first PMIC chip 204-1 and the second PMIC chip 204-2). The solder layer 1004 is part of the metal-solder structure 1001. In particular, the first metal plate 906 of the PCB 808 is electrically coupled to a respective PMIC chip (e.g., 204-1) through a respective thermal solder layer (e.g., 1004-1) and a respective metallization layer (e.g., 1002-1). Compared to the first thermal conducting layer 904 (in FIG. 9A), the metal-solder structure 1001 further improves heat conduction, because alloys (e.g., tin, silver, or indium) provide significantly better thermal conductivity. Moreover, the metal-solder structure 1001 provides ultra-thin and consistent bond lines for the circuit package 800. Additionally, the metal-solder structure 1001 allows the plurality of PMIC chips 204 to bond to the first metal plate 906 of the PCB 808 during a reflow process. In some implementations, the solder layer 1004 includes a solder paste (e.g., alloys having tin, silver, copper, and/or indium). In some implementations, a selection between the example architecture 900 and the example architecture 1000 depends on specifications of the circuit package 800, including electrical requirements, thermal requirements, curing requirements, and operating temperatures.

FIG. 10B is a cross-section view of another example architecture 1050 of the circuit package 800 that includes the thermal path 802 (e.g., a thermal via) having the plurality of via groups 952 and the metal-solder structure 1001 connecting the plurality of PMIC chips 204 to the PCB 808, in accordance with some implementations. Similar to the example architecture 950 (in FIG. 9B), the first metal plate 906 of the PCB 808 in the example architecture 1050 includes the plurality of metal plates 910 (e.g., respective metal plates 910-1 and 910-2). Each of the plurality of metal plates (e.g., 910-1) of the PCB 808 is electrically coupled to a respective PMIC chip (e.g., 204-1) through a respective thermal solder layer (e.g., 1004-1) and a respective metallization layer (e.g., 1002-1). Each via group (e.g., 952-1) has a plurality of vias (e.g., 902-1, 902-2, and 902-3) and is coupled to a respective PMIC chip (e.g., 204-1) through a respective metal plate (e.g., 910-1).

In some implementations, the plurality of metal plates 910 (e.g., 910-1 and 910-2) are discrete and not physically coupled on the first side 810-1 of the PCB 808. The discrete plurality of metal plates 910 (e.g., 910-1 and 910-2) are implemented to improve heat spreading in conjunction with placement of vias within the plurality of via groups 952. In some implementations, the plurality of metal plates 910 (e.g., 910-1 and 910-2) of the PCB 808 include distinct geometries from one another.

FIG. 11 is a cross-section view of an example architecture 1100 of the circuit package 800 that includes the thermal path 802 (e.g., a thermal via) defining a vacancy 1102 that allows a second heat exchanger 1104 to be coupled to the plurality of PMIC chips 204, in accordance with some implementations. In the example architecture 1100, the thermal path 802 defines the vacancy 1102. The circuit package 800 includes the second heat exchanger 1104 coupled to the plurality of PMIC chips 204 through the vacancy 1102. In particular, the vacancy 1102 provides a space that allows the second heat exchanger 1104 be coupled to the plurality of PMIC chips 204. In some implementations, the vacancy 1102 includes a hole, a cavity, or other type, which is created on the PCB 808 during PCB manufacturing. Alternatively, in some implementations, the second heat exchanger 1104 is implemented in the example architectures 900, 950, 1000, and/or 1050.

In some implementations, the second heat exchanger 1104 includes a device configured to transfer heat between components (e.g., the plurality of PMIC chips 204, the substrate 804, the processor 806, etc.). In some implementations, the second heat exchanger 1104 includes a second plurality of heat sinks 1106 (e.g., respective heat sinks 1106-1 and 1106-2). Each heat sink (e.g., 1106-1) of the second plurality of heat sinks 1106 is coupled to a respective PMIC chip (e.g., 204-1) of the plurality of PMIC chips 204. In particular, the second plurality of heat sinks 1106 is coupled to the back side 812-2 of the plurality of PMIC chips 204. In some implementations, compared to the first thermal conducting layer 904 (in FIG. 9A) and the metal-solder structure 1001 (in FIG. 10A), the second plurality of heat sinks 1106 are configured to actively dissipate heat (e.g., using fans or liquids) from the plurality of PMIC chips 204 to ambient, thereby maximizing thermal management with greater reliability and longer lifespan. In particular, the second plurality of heat sinks 1106 increases surface area for heat dissipation and is capable of dissipating heat for high-power or heat-intensive components (e.g., high-power applications associated with the plurality of PMIC chips 204 and the processor 806). In some implementations, a selection (e.g., models, types, etc.) of the second plurality of heat sinks 1106 depends on specifications of the circuit package 800, including electrical requirements, thermal requirements, curing requirements, and operating temperatures.

In some implementations, the circuit package 800 includes an adhesive layer 1108 (e.g., respective adhesive layers 1108-1 and 1108-2) disposed between the second heat exchanger 1104 and the plurality of PMIC chips 204. In particular, the second heat exchanger 1104 is coupled to the back side 812-2 of the plurality of PMIC chips 204 through the adhesive layer 1108. In some implementations, the adhesive layer 1108 includes at least one of the group consisting of a thermally conductive adhesive tape, a thermal adhesive epoxy, a silicone-based thermal adhesive, a thermal conductive gel, and a phase change material. In some implementations, a selection of material(s) of the adhesive layer 1108 depends on specifications of the circuit package 800, including electrical requirements, thermal requirements, curing requirements, and operating temperatures.

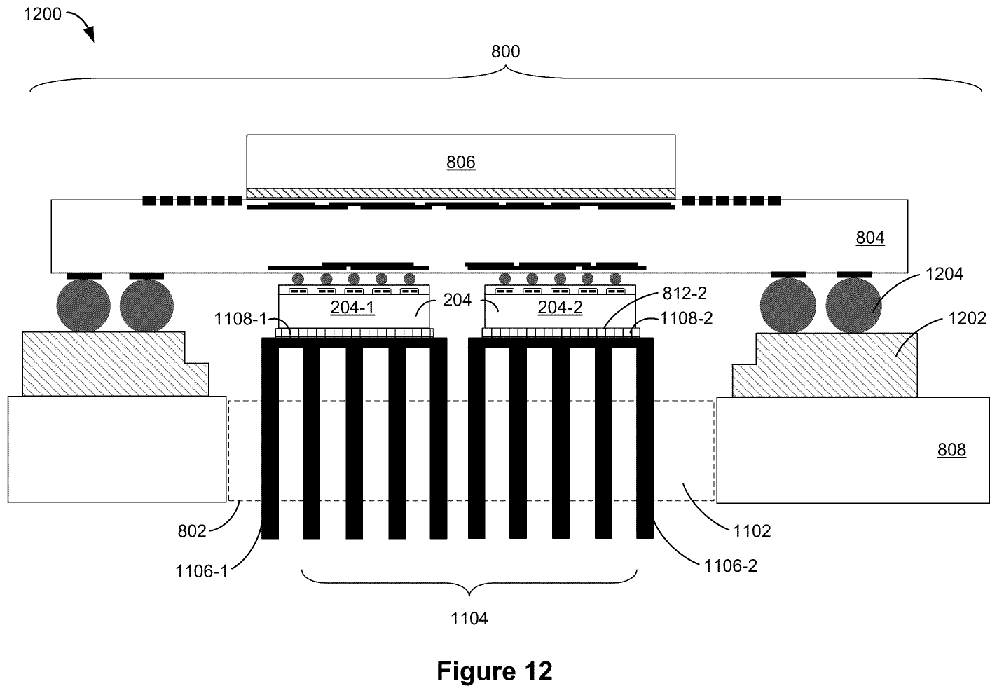

FIG. 12 is a cross-section view of an another example architecture 1200 of the circuit package 800 that includes a second heat exchanger 1104 for heat dissipation and a socket 1202 for positioning the substrate 804 on the PCB 808, in accordance with some implementations. In some implementations, the circuit package 800 includes a socket 1112 coupled to and positioned between the PCB 808 and the substrate 804. The socket 1112 is mounted on the PCB 808 and coupled (e.g., electrically coupled) to the substrate 804 through solder balls 1204 (e.g., solder bumps). In some implementations, the socket 1112 is a replaceable component, providing a convenient way to connect the substrate 804 to the PCB 808 without permanent soldering. In some implementations, the socket 1112 is implemented in the example architecture 1200 to reduce stress on the PCB 808 from mechanical vibrations and eliminate risk of stress-related failure.

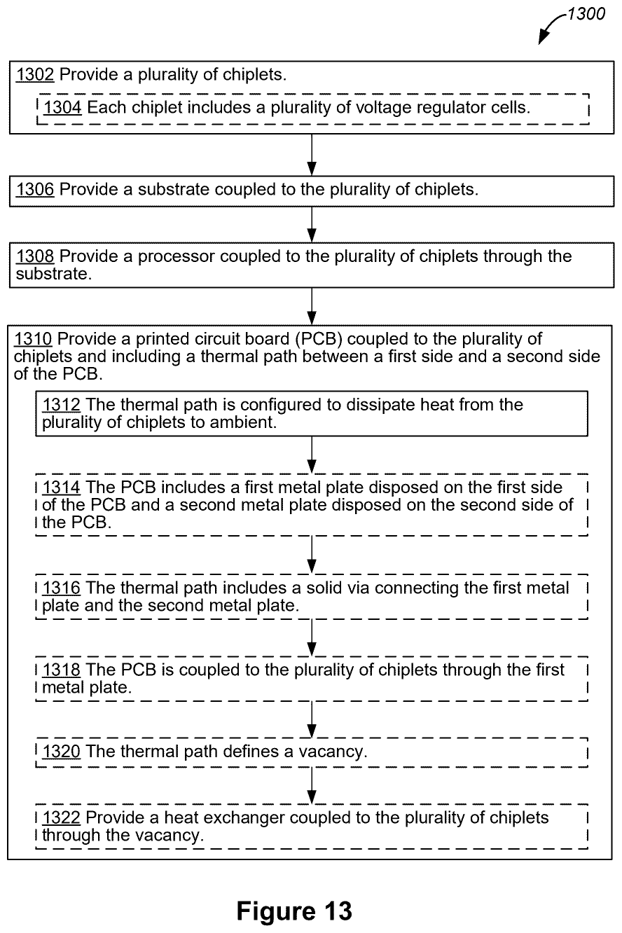

FIG. 13 is a flow diagram of an example method 1300 for providing the circuit package 800, in accordance with some implementations. The method 1300 includes providing (operation 1302) a plurality of chiplets (e.g., PMIC chips 204). Each chiplet includes (operation 1304) a plurality of voltage regulator cells 406. The method 1300 further includes providing (operation 1306) a substrate 804 coupled to the plurality of chiplets (e.g., PMIC chips 204). The method 1300 further includes providing (operation 1308) a processor 806 coupled to the plurality of chiplets (e.g., PMIC chips 204) through the substrate 804. The method 1300 further includes providing (operation 1310) a printed circuit board (PCB) 808 coupled to the plurality of chiplets (e.g., PMIC chips 204) and including a thermal path 802 between a first side 810-1 and a second side 810-2 of the PCB 808. The thermal path 802 is configured to dissipate (operation 1312) heat from the plurality of chiplets (e.g., PMIC chips 204) to ambient.

In some implementations, the PCB 808 includes (operation 1314) a first metal plate 906 disposed on the first side 810-1 of the PCB 808 and a second metal plate 908 disposed on the second side 810-2 of the PCB 808. The thermal path 802 includes (operation 1316) a solid via 902 connecting the first metal plate 906 and the second metal plate 908. The PCB 808 is coupled (operation 1318) to the plurality of chiplets (e.g., PMIC chips 204) through the first metal plate 906.

In some implementations, the thermal path 802 defines (operation 1320) a vacancy 1102. The method 1300 further includes providing (operation 1322) a second heat exchanger 1104 coupled to the plurality of chiplets (e.g., PMIC chips 204) through the vacancy 1102.

Various examples of aspects of the disclosure are described as numbered clauses (1, 2, 3, etc.) for convenience. These are provided as examples, and do not limit the subject technology. Identifications of the figures and reference numbers are provided below merely as examples and for illustrative purposes, and the clauses are not limited by those identifications.

Clause 1. An circuit package 800, comprising: a plurality of chiplets (e.g., PMIC chips 204); a substrate 804 coupled to the plurality of chiplets (e.g., PMIC chips 204); a processor 806 coupled to the plurality of chiplets (e.g., PMIC chips 204) through the substrate 804; and a printed circuit board (PCB) 808 coupled to the plurality of chiplets (e.g., PMIC chips 204) and including a thermal path 802 between a first side 810-1 and a second side 810-2 of the PCB 808, wherein the thermal path 802 is configured to dissipate heat from the plurality of chiplets (e.g., PMIC chips 204) to ambient.

Clause 2. The circuit package 800 of clause 1, wherein each chiplet includes a plurality of voltage regulator cells.

Clause 3. The circuit package 800 of clause 1-2, wherein the plurality of voltage regulator cells 406 include an times m array 404, n and m being integers and a number of the plurality of voltage regulator cells 406 being greater than two.

Clause 4. The circuit package 800 of any of clauses 1-3, wherein the plurality of voltage regulator cells 406 are configured to provide a plurality of voltage regulator sets 410, and each voltage regulator set is configured to output a respective rail voltage V_{RAIL}.

Clause 5. The circuit package of any of clauses 1-4, wherein the substrate 804 includes an organic material.

Clause 6. The circuit package 800 of any of clauses 1-5, wherein the processor 806 includes a system-on-chip (SOC).

Clause 7. The circuit package 800 of any of clauses 1-6, wherein the PCB 808 further includes a first metal plate 906 disposed on the first side 810-1 of the PCB and a second metal plate 908 disposed on the second side 810-2 of the PCB 808; the thermal path 802 includes a solid via 902 connecting the first metal plate 906 and the second metal plate 908; and the PCB 808 is coupled to the plurality of chiplets (e.g., PMIC chips 204) through the first metal plate 906.

Clause 8. The circuit package 800 of any of clauses 1-7, wherein the solid via 902 includes one or more vias (e.g., vias 902-1, 902-2, 903-3, . . . , 902-k).

Clause 9. The circuit package 800 of any of clauses 1-8, wherein the first metal plate 906 includes a plurality of metal plates 910; and the solid via 902 includes a plurality of via groups 952, each via group having a plurality of vias and coupled to a respective chiplet of the plurality of chiplets (e.g., PMIC chips 204) through a respective plate of the plurality of metal plates 910.

Clause 10. The circuit package 800 of any of clauses 1-9, wherein the solid via 902 includes a metal material.

Clause 11. The circuit package 800 of any of clauses 1-10, further comprising: a thermal conducting layer (e.g., 904) disposed between the first metal plate 906 and the plurality of chiplets (e.g., PMIC chips 204).

Clause 12. The circuit package 800 of any of clauses 1-11, wherein the plurality of chiplets (e.g., PMIC chips 204) include a metallization layer 1002, the circuit package further comprising: a solder layer 1004 disposed between the first metal plate 906 and the metallization layer 1002 of the plurality of chiplets (e.g., PMIC chips 204).

Clause 13. The circuit package 800 of any of clauses 1-12, further comprising: a first heat exchanger coupled to the second metal plate of the PCB.

Clause 14. The circuit package 800 of any of clauses 1-13, wherein the first heat exchanger includes a first plurality of heat sinks.

Clause 15. The circuit package 800 of any of clauses 1-14, wherein the first heat exchanger is liquid-cooled.

Clause 16. The circuit package 800 of any of clauses 1-15, wherein the thermal path 802 defines a vacancy 1102, the circuit package further comprising: a second heat exchanger 1104 coupled to the plurality of chiplets (e.g., PMIC chips 204) through the vacancy 1102.

Clause 17. The circuit package 800 of any of clauses 1-16, wherein the second heat exchanger 1104 includes a second plurality of heat sinks, each of the second plurality of heat sinks 1106 coupled to a respective chiplet of the plurality of chiplets (e.g., PMIC chips 204).

Clause 18. The circuit package 800 of any of clauses 1-17, further comprising: a socket 1112 coupled to and positioned between the PCB 808 and the substrate 804.

Clause 19. The circuit package 800 of any of clauses 1-18, further comprising: an adhesive layer 1108 disposed between the second heat exchanger 1104 and the plurality of chiplets (e.g., PMIC chips 204).

Clause 20. A method, comprising: providing a plurality of chiplets (e.g., PMIC chips 204); providing a substrate 804 coupled to the plurality of chiplets (e.g., PMIC chips 204); providing a processor 806 coupled to the plurality of chiplets (e.g., PMIC chips 204) through the substrate 804; and providing a printed circuit board (PCB) 808 coupled to the plurality of chiplets (e.g., PMIC chips 204) and including a thermal path 802 between a first side and a second side of the PCB 808, wherein the thermal path 802 is configured to dissipate heat from the plurality of chiplets (e.g., PMIC chips 204) to ambient.

The terminology used in the description of the various described implementations herein is for the purpose of describing particular implementations only and is not intended to be limiting. As used in the description of the various described implementations and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. Additionally, it will be understood that, although the terms “first,” “second,” etc. may be used herein to describe various elements, these elements should not be limited by these terms. These terms are only used to distinguish one element from another.

As used herein, the term “if” is, optionally, construed to mean “when” or “upon” or “in response to determining” or “in response to detecting” or “in accordance with a determination that,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event]” or “in accordance with a determination that [a stated condition or event] is detected,” depending on the context.

The foregoing description, for purpose of explanation, has been described with reference to specific implementations. However, the illustrative discussions above are not intended to be exhaustive or to limit the claims to the precise forms disclosed. Many modifications and variations are possible in view of the above teachings. The implementations were chosen and described in order to best explain principles of operation and practical applications, to thereby enable others skilled in the art.

Although various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages can be implemented in hardware, firmware, software or any combination thereof.

What is claimed is:

1. A circuit package, comprising:
a plurality of chiplets;
a substrate coupled to the plurality of chiplets;
a processor coupled to the plurality of chiplets through the substrate; and
a printed circuit board (PCB) coupled to the plurality of chiplets and including a thermal path between a first side and a second side of the PCB, wherein the thermal path is configured to dissipate heat from the plurality of chiplets to ambient.

2. The circuit package of claim 1, wherein each chiplet includes a plurality of voltage regulator cells.

3. The circuit package of claim 2, wherein the plurality of voltage regulator cells include a n times m array, n and m being integers and a number of the plurality of voltage regulator cells being greater than two.

4. The circuit package of claim 2, wherein the plurality of voltage regulator cells are configured to provide a plurality of voltage regulator sets, and each voltage regulator set is configured to output a respective rail voltage.

5. The circuit package of claim 1, wherein the substrate includes an organic material.

6. The circuit package of claim 1, wherein the processor includes a system-on-chip (SOC).

7. The circuit package of claim 1, wherein:
the PCB further includes a first metal plate disposed on the first side of the PCB and a second metal plate disposed on the second side of the PCB;
the thermal path includes a solid via connecting the first metal plate and the second metal plate; and
the PCB is coupled to the plurality of chiplets through the first metal plate.

8. The circuit package of claim 7, wherein the solid via includes one or more vias.

9. The circuit package of claim 7, wherein:
the first metal plate includes a plurality of metal plates; and
the solid via includes a plurality of via groups, each via group having a plurality of vias and coupled to a respective chiplet of the plurality of chiplets through a respective plate of the plurality of metal plates.

10. The circuit package of claim 7, wherein the solid via includes a metal material.

11. The circuit package of claim 7, further comprising:
a thermal conducting layer disposed between the first metal plate and the plurality of chiplets.

12. The circuit package of claim 7, wherein the plurality of chiplets include a metallization layer, the circuit package further comprising:
a solder layer disposed between the first metal plate and the metallization layer of the plurality of chiplets.

13. The circuit package of claim 7, further comprising:
a first heat exchanger coupled to the second metal plate of the PCB.

14. The circuit package of claim 13, wherein the first heat exchanger includes a first plurality of heat sinks.

15. The circuit package of claim 13, wherein the first heat exchanger is liquid-cooled.

16. The circuit package of claim 1, wherein the thermal path defines a vacancy, the circuit package further comprising:
a second heat exchanger coupled to the plurality of chiplets through the vacancy.

17. The circuit package of claim 16, wherein the second heat exchanger includes a second plurality of heat sinks, each of the second plurality of heat sinks coupled to a respective chiplet of the plurality of chiplets.

18. The circuit package of claim 16, further comprising:
a socket coupled to and positioned between the PCB and the substrate.

19. The circuit package of claim 16, further comprising:
an adhesive layer disposed between the second heat exchanger and the plurality of chiplets.

20. A method for providing a circuit package, comprising: providing a plurality of chiplets;
providing a substrate coupled to the plurality of chiplets;
providing a processor coupled to the plurality of chiplets through the substrate; and
providing a printed circuit board (PCB) coupled to the plurality of chiplets and including a thermal path between a first side and a second side of the PCB, wherein the thermal path is configured to dissipate heat from the plurality of chiplets to ambient.
